(19) United States
(12) Patent Application Publication
(10) Pub. No.: US 2026/0229071 A1
(43) Pub. Date: Aug. 6, 2026

(54) Method, System for Carrying Out Such a Method; Computer Program and Computer-Readable Medium for Generating a Test Profile for Vibration Testing of Vehicle Equipment on the Basis of Data Acquisition During Route Journeys

(71) Applicant: ZF Friedrichshafen AG, Friedrichshafen (DE)

(72) Inventor: Yuriy Ivanov, Langenargen (DE)

(21) Appl. No.: 19/151,205

(22) PCT Filed: Jan. 25, 2024
(86) PCT No.: PCT/EP2024/051729

§ 371 Date: Jul. 25, 2025

(30) Foreign Application Priority Data
Jan. 25, 2023 (DE) 10 2023 200 580.8

(51) Int. Cl. G07C 5/04; G01M 17/007

(52) U.S. Cl. CPC G07C 5/04; G01M 17/007

(57) ABSTRACT

A method for generating a test profile includes calculating, using a spectrum calculation algorithm, a plurality of pseudo-damage spectra from a plurality of measurement signals previously recorded during a route journey of a test vehicle. The method further includes an extrapolation and superposition process where a plurality of extrapolated pseudo-damage spectra are generated by multiplying each of the pseudo-damage spectrum by a proportionality constant, and a superposed pseudo-damage spectrum is generated by adding together the plurality of extrapolated pseudo-damage spectra. Further, the method includes calculating a reference signal pseudo-damage spectrum using the spectrum calculation algorithm on a reference signal, and an extrapolated reference signal pseudo-damage spectrum by multiplying the reference signal pseudo-damage spectrum by the proportionality constant. Additionally, the method includes generating the test profile based on the superposed pseudo-damage spectrum and the extrapolated reference signal pseudo-damage spectrum.

### CROSS-REFERENCE TO RELATED APPLICATION

The present application is related and has right of priority to German Patent Application No. 10 2023 200 580.8 filed on Jan. 25, 2023 and is a nationalization of PCT/EP2024/051729 filed in the European Patent Office on Jan. 25, 2024, both of which are incorporated by reference in their entirety for all purposes.

### TECHNICAL FIELD

The invention relates generally to a method for generating a test profile, to a system for carrying out such a method, to a computer program, and to a computer-readable medium.

### BACKGROUND

In the context of release processes for newly developed technical products in the automobile industry—inter alia—, typically the vibration resistance of such products is analyzed. The products are all types of components, assemblies, or devices that are installed in vehicles and are exposed to vibrations during the operation of these vehicles. These can be vibrations generated by the operation of the vehicle or vibrations generated by the products themselves (for example, in electric motors), or a combination of different types of vibrations.

In tests for the vibration resistance of such products, the products are typically exposed to certain vibration patterns on specific test rigs (for example, shaker rigs), which vibration patterns are intended to simulate, as closely as possible, the vibrations occurring during the operation of a vehicle in which the products are to be used. Such vibration patterns are defined by test profiles.

Ideally, such test profiles should reflect, as realistically as possible, the vibration loads for the particular products during their service life. Such test profiles should also make it possible, however, to keep the duration of the vibration tests on the test rigs as short as possible, for example, in order to minimize the costs for the vibration tests.

DE 10 2020 114 973 A1 relates to a method for determining a test profile for tests or simulations on a component to be tested or on a motor vehicle. In the method, data are measured or calculated as a function of time during different use cases and stored. These data are then analyzed for damage content. The identified damage content of a certain use case is made available to the user. The user can then select specific time periods from various use cases and combine these to create a customized test profile.

In the past, inventions had already related to methods for creating test profiles that are determined, for example, on the basis of data recorded during test drives.

Disadvantages of the known methods for creating profiles are briefly described in the following. For greater clarity, the methods have been grouped according to the features “model-based/non-model-based,” and “damage-based/non-damage based.”

The model-based methods are based on describing dynamic properties of the analyzed component using a physical system model, for example, in the form of a finite element (FE) model [10, 11] (references to the list of references at the end of the description are provided in brackets), or mathematically, by a set of differential equations [5-9]. If the profile calculation algorithm is defined such that a profile created using the profile calculation algorithm is intended to satisfy the (computational) equality of the damage figures from measurements of operational vibrations (for example, in the vehicle on routes) with those from the shaker test (the principle of damage equivalence), the profile calculation algorithm is attributed to the damage-based method.

The greatest disadvantages of these methods are:
The profile calculated using a non-damage-based method (regardless of whether it is model-based or non-model-based) does not ensure that the damage that the product sustains during its life cycle in a vehicle (operational damage) is reproduced in a vibration test (test damage). Therefore, when a test has been passed, it is not ruled out that the damage caused to the product in the vibration test was too little as compared to the actual damage in the vehicle (i.e., the test was too weak). However, when a test has not been passed, the test damage could exceed the operational damage (the test is too severe). In both cases, this would indicate that a test was not carried out correctly. All non-damage-based methods, for example, [2, 3, 4], have this disadvantage.
In model-based methods, the model of a linear Single Degree of Freedom (SDOF) system with low damping is used to describe the vibration characteristics of the test specimen. This is the case with the methods [5-9]. However, a complex, non-linear, mechanical-dynamic behavior of real products (components) can be only inaccurately represented by a relatively simple SDOF model. In the other methods [10, 11], a computer model created by a finite element tool is used for this purpose. Creating an FE model requires a large amount of work, however, and therefore leads to high costs for the profile calculation.

Other disadvantages of the profile creation methods known from the prior art for the vibration testing of vehicle equipment are:
they are not universally usable, since they can be used to calculate [13] either
   profiles of a certain type (for example, only sweep profiles [2, 3] or only noise profiles [4, 9, 12, 13]), or
   profiles only for the excitation of vibrations (in other words—excitation profiles) but not for the vibration response (response profiles that enable, for example, limitation of the response amplitudes of the test specimen when an excitation profile is applied) [4-9], or
   profiles that permit a damage-equivalent test only for a certain combination of the calculation parameters (for example, only for the slope coefficient 4 of the S-N curve), or
in order to trigger the profile calculation algorithm, they require data that have been recorded on a vibration test rig, optionally in a pre-test [13]; according to the invention, it was recognized that such data can be generated through simulation even without the use of hardware (for example, on a test rig), which minimizes effort and costs, or
they function only recursively [8, 9, 13]; this is inefficient and results in high computational complexity, since the profile amplitude for each individual frequency must be calculated iteratively, in a loop, or
they do not account for the need for the extrapolation and the superposition of the load spectra or the damage figures, calculated from the data recorded in driving tests, so that they apply for a full required service life of the component in the vehicle [13].

### SUMMARY OF THE INVENTION

The problem addressed by the invention is that of eliminating or at least diminishing the disadvantages of the prior art.

The problem is solved by a method for creating a test profile. The inventor has recognized that this problem can be solved particularly well by a novel, damage-based and non-model-based method for creating a test profile.

The term “test profile” is to be understood broadly in this case. In particular, a test profile is understood to be, for example, the following functional dependencies:
the curve of the amplitude of an acceleration signal (or another physical variable) with respect to the frequency (in particular in sweep profiles),
the curve of the Power Spectral Density (PSD) (referred to as “LDS” in German-language priority documents) of an acceleration signal (or another physical variable) with respect to the frequency (in particular in noise profiles).

The inventors have determined that such a method for creating a test profile can be more versatile and efficient than the known methods. This method according to the invention is referred to in the following as the Automated Vibration Profile Development method or as the “ASPEN” or “ASPEN RoMi” method. It is used to create the test profiles from test drives on routes. The routes are understood to be specific driving routes (for example, on a highway, an interurban route, a mountain road, in city) defined for various use profiles of the vehicle; during test drives on these routes, realistic conditions with respect to the vibration load on the component under consideration are simulated. The routes can be combined in any ratio, as a Route Mix—which gives rise to the name “RoMi”. A known user of the route mix in the passenger car segment is CARLOS [1, 15].

A distinction is to be made between route journeys and special tests. Special tests are understood to be tests of a relatively short duration having a uniform, continuous rise (“run up”) or fall (“run down”) of one or more vehicle state parameter(s). This parameter is usually a rotational speed in the drive train of the vehicle, for example, the rotational speed of the internal combustion engine or of the electric propulsion unit (in electric vehicles). Since the dwell time of the vehicle state parameters in these tests generally does not correspond to the typical operational use, they are not suitable for creating test profiles using the ASPEN RoMi method.

The data required to create the profile are preferably recorded, as described above, in a test vehicle during the test drives on one or more routes (route mix). Alternatively, a suitable functional test rig and/or load test rig is usable when it permits the simulation of vibrations that the product undergoes similarly to the journeys in a vehicle on routes. In such tests, mechanical-dynamic load and/or stress variables (for example, of the vibration acceleration, vibration velocity, of the dynamic vibration displacement, of the dynamic forces, mechanical strain, among other things) having an oscillating curve are measured on the product and/or at the attachment points of the product on the carrier by suitable sensors (for example, acceleration sensors, speed sensors, displacement sensors, force sensors, strain gauges, etc.) and a suitable vibration detection system.

After the conclusion of a measurement campaign carried out in this way, the input data required to create the profile using the ASPEN method are present as digitized vibration signals. After signal preprocessing using a common approach known to a person skilled in the art (for example, eliminating measurement interferences, extracting relevant measurement intervals, filtering), the input data is feedable directly to the computing unit or to the other system in which the ASPEN program is programmed, for the profile calculation.

For the calculation of the test profile, apart from the signals recorded on the routes, a specific time signal, which is referred to as the reference signal, is advantageously processed in the ASPEN method.

In advantageous embodiments, all test profiles calculated by the method computationally satisfy the principle of damage equivalence with respect to the pseudo-damage spectra calculated in the method.

In advantageous embodiments, the reference signal processing process runs in parallel with the pseudo-damage spectrum calculation process and/or with the extrapolation and superposition process. One advantage thereof is that both the superposed pseudo-damage spectrum and the extrapolated reference signal pseudo-damage spectrum are available for the test profile generation process substantially at the same time. In typical embodiments, the reference signal pseudo-damage spectrum is calculated in the context of the pseudo-damage spectrum calculation process. In typical embodiments, the extrapolated reference signal pseudo-damage spectrum is calculated in the context of the extrapolation and superposition process, in particular in the context of the extrapolation subprocess. Alternatively, it is also possible, however, to calculate the reference signal in another way, for example, at other points in time.

In this case, each measurement signal preferably describes a time curve of a respective measurement variable, typically recorded on various routes of a route mix. This is to be understood, in particular, to mean that a measurement variable, for example, acceleration, is defined at a certain point on a component of a vehicle in a certain measurement direction. This measurement variable is then considered in the context of a plurality of route journeys of a test vehicle and, for each route journey, a measurement signal of this measurement variable is always recorded in an identical direction. At the end of the plurality of route journeys, there is, therefore, a plurality of measurement signals (in other words—a set of measurement signals) for the respective measurement variable—one measurement signal for each route. The measurement signals differ more or less in terms of their curve, because the route journeys each cause different vibrations.

In a first example of the method, a set of measurement signals of only one measurement variable is processed. The method then delivers (as the main result) only one test profile. Using the test profile, an identical stress of the type that likely arises on the route mix for the full required period of operation (service life) is applied to the component (at its selected point of measurement) in a vibration test having a defined duration. “Likely” means that the operational damage is computationally predicted by the extrapolation and superposition process. In this sense, the method delivers damage-equivalent profiles. The principle of damage equivalence is used to define the method and is the most important characteristic of the method.

In a second example, multiple test profiles are generated on the basis of a plurality of sets of measurement signals in the context of the method, each set of measurement signals being obtained by measuring the signals of a certain measurement variable on the route mix. In other words, not only is one measurement variable considered, but rather a plurality of measurement variables is considered in the method. It is conceivable, for example, that accelerations are supposed to be measured on a certain component in a vehicle at different points on the component in an identical direction. The particular acceleration at each measuring point in one direction is considered to be a dedicated measurement variable. This yields a plurality of sets of measurement signals for this component, each set of measurement signals corresponding to a certain measurement variable. Instead of a plurality of measurement signals for a certain measurement variable, there are, therefore, different sets of measurement signals, each set of measurement signals consisting of a number of measurement signals that corresponds to the number of completed route journeys of the test vehicle (since preferably one signal of an identical measurement variable is recorded per route in all embodiments of the method). In situations having a plurality of sets of measurement signals, in the context of the aforementioned processes, instead of the measurement signals for only one single measurement variable, different sets of measurement signals are therefore processed for the plurality of measurement variables, the number of sets of measurement signals corresponding to the number of measurement variables under consideration. In other words, the simplest case of the method according to the invention (see the first example) therefore corresponds to the case in which only one measurement variable is considered. In the latter, second example, however, two, three, four or more measurement variables are considered in the method, the particular measurement signals of which are incorporated into the calculations of the aforementioned processes. In this case, after the extrapolation and superposition process has been carried out, the method delivers multiple profiles, each of which is damage-equivalent in the aforementioned sense for the considered point and direction on the component (i.e., for the particular measurement variable).

The method is also typically based on the calculation of the pseudo-damage spectra.

In typical embodiments, in the context of the method (regardless of the task, the input data, and the setting parameters), test profiles of multiple different types or profiles having various features, such as excitation and response profiles, profiles for single-point control and multi-point control, and profiles that cover the damage on individual routes or on the entire route mix, are generated.

In advantageous embodiments, the pseudo-damage spectrum calculation process includes the following steps:
a signal filter step, in the context of which each measurement signal is filtered by a plurality of band passes, so that a plurality of filtered measurement signals arises,
a classification step, in the context of which a load spectrum is formed from each filtered measurement signal by a classification, typically by subdividing an entire amplitude range of each filtered measurement signal into classes, a number of stress cycles preferably being determined for the amplitude of each class using a counting method,
a conversion step, in the context of which an amplitude, which optionally has an average value, of each stress cycle (a stress cycle may have an average value unequal to zero) is initially converted into a damage-equivalent amplitude that does not have an average value, preferably by a Haigh diagram, and the amplitudes that do not have an average value are then sorted in ascending order,
a partial damage contribution calculation step, in the context of which a partial damage contribution is calculated, preferably by utilizing an S-N curve, for the number of stress cycles at each damage-equivalent amplitude that does not have an average value,
a cumulative damage calculation step, in the context of which the partial damage contributions are summed to obtain a cumulative damage for each filtered measurement signal, each cumulative damage being referred to as a pseudo-damage figure of the particular filtered measurement signal, and
a pseudo-damage spectrum formation step, in the context of which the pseudo-damage spectra are formed from the pseudo-damage figures by representing the pseudo-damage figures as a function of the band pass central frequencies of the band passes.

The filtered measurement signals are preferably narrow-band filtered measurement signals. In typical embodiments, the classification step includes a rainflow counting step, in the context of which a rainflow matrix is created for each filtered measurement signal using rainflow parameters. In the following, the term “pseudo-damage spectrum” is abbreviated as “PSS” in some points for the sake of simplicity.

In advantageous embodiments, a calculation of a noise profile and/or a calculation of a sweep profile is carried out in the context of the test profile generation process.

In typical embodiments, the sweep profile is calculated according to the following formula:

$${S}_{U} ( f ) = {S}_{R e f} ( f ) \times {[ \frac{{D}_{U} ( f )}{{D}_{R e f} ( f )} ]}^{( \frac{1}{{k}_{W L}} )}$$

wherein
S_{U}(f) is the sought amplitude of the amplitude frequency curve (AFV) of the sweep profile,
S_{Ref}(f) is the amplitude of the AFV of the monoharmonic reference signal,
D_{U}(f) is the ordinate of the PSS that arises for monoharmonic vibration having the sought amplitude S_{U},
D_{Ref}(f) is the ordinate of the PSS of the reference signal having the AFV S_{Ref}(f), and
k_{WL} is the slope coefficient of the S-N curve.

In typical embodiments, the noise profile is calculated according to the following formula:

$$P S {D}_{U} ( f ) = P S {D}_{R e f} ( f ) \times {[ \frac{{D}_{U} ( f )}{{D}_{R e f} ( f )} ]}^{( \frac{2}{{k}_{W L}} )}$$

wherein
PSD_{U}(f) is the sought level of the Power Spectral Density (PSD) of the noise profile,
PSD_{Ref}(f) is the level of the PSD of the stochastic reference signal,
D_{U}(f) is the ordinate of the PSS that arises for stochastic vibration having the sought PSD PSD_{U},
D_{Ref}(f) is the ordinate of the PSS of the reference signal having the PSD PSD_{Ref}(f), and
k_{WL} is the slope coefficient of the S-N curve.

In typical embodiments, the method is a computer-implemented method. In typical embodiments, the method runs in an automated manner, at least in part.

The problem is also solved by a system for carrying out one of the aforementioned methods, wherein the system is preferably suitable for at least partially carrying out and/or coordinating and/or controlling a method for creating a test profile according to at least one of the aforementioned embodiments.

For this purpose, the system advantageously includes suitable components, for example, a pseudo-damage spectrum calculation component and/or a spectrum calculation component and/or an extrapolation and superposition component and/or an extrapolation subcomponent and/or a superposition subcomponent and/or a test profile generation component and/or a reference signal processing component and/or a signal filter component and/or a classification component and/or a conversion component and/or a partial damage contribution calculation component and/or a cumulative damage calculation component and/or a pseudo-damage spectrum formation component and/or a noise profile calculation component and/or a sweep profile calculation component.

Advantageously, at least some of the aforementioned components are implemented in the system by computer program code.

The problem is also solved by a computer program including steps which, when run on a computer, prompt the computer to carry out a method for creating a test profile according to at least one of the aforementioned embodiments.

A computer-readable medium includes, in one embodiment of the invention, computer program code for carrying out one of the aforementioned methods. The term “computer-readable medium” is to be understood, in particular but not exclusively, as hard drives and/or servers and/or memory sticks and/or flash drives and/or DVDs and/or Bluerays and/or CDs. The term “computer-readable medium” is also to be understood as a data stream of the type that arises, for example, when a computer program product is downloaded from the Internet.

### BRIEF DESCRIPTION OF THE DRAWINGS

The invention is explained briefly in the following with reference to drawings, in which:

FIG. 1: shows a schematic view of a method according to the invention as a block diagram;

FIG. 2: shows a schematic view of a method according to further aspects of the invention in a second a block diagram;

FIG. 3: shows a schematic view of a pseudo-damage spectrum calculation process of the type that is typically used in a method according to the invention, as a block diagram,

FIG. 4: shows a schematic view of a method according to the invention in another block diagram,

FIG. 5: shows a schematic view of a pseudo-damage spectrum calculation process of the type that is typically used in a method according to the invention,

FIG. 6: shows a schematic view of an extrapolation and superposition process for a plurality of measurement variables,

FIG. 7: shows a schematic view of a test profile generation process for a plurality of measurement variables,

FIG. 8: shows an exemplary representation of load spectra and an S-N curve, and

FIG. 9: shows a schematic view of a method according to even further aspects of the invention in a further block diagram.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

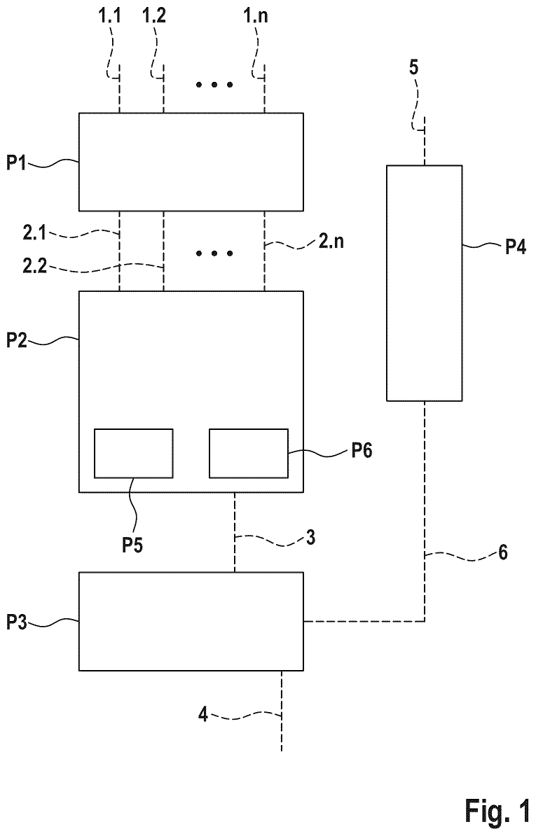

FIG. 1 shows a schematic view of a method according to the invention in a a block diagram. In particular, FIG. 1 shows a pseudo-damage spectrum calculation process P1, an extrapolation and superposition process P2, a test profile generation process P3, and a reference signal processing process P4. The extrapolation and superposition process P2 includes an extrapolation subprocess P5 and a superposition subprocess P6. A plurality of measurement signals 1.1, 1.2, . . . , 1.n is fed to the pseudo-damage spectrum calculation process. These measurement signals 1.1, 1.2, . . . , 1.n are typically recorded during routine journeys of a test vehicle (not shown) and each represents the time curve of a certain oscillating measurement variable in the test vehicle. Each of the “n” measurement signals 1.1, 1.2, . . . , 1.n is measured on a certain route of the test vehicle, so that one measurement signal per travel route is present for the profile calculation. In the pseudo-damage spectrum calculation process P1, these measurement signals 1.1, 1.2, . . . , 1.n are used to calculate a plurality of pseudo-damage spectra 2.1, 2.2., . . . , 2.n by a spectrum calculation algorithm. This yields a pseudo-damage spectrum 2.1, 2.2, . . . , 2n for each measurement signal 1.1., 1.2, . . . 1.n. Details of the pseudo-damage spectrum calculation process P1 are explained in greater detail in the following. The pseudo-damage spectra 2.1, 2.2, . . . , 2n are then fed to the extrapolation and superposition process P2. In this context, each pseudo-damage spectrum 2.1, 2.2, . . . , 2n is initially multiplied by a proportionality constant (e.g., in the extrapolation subprocess P5), so that a plurality of extrapolated pseudo-damage spectra is created. For the sake of greater clarity, the extrapolated pseudo-damage spectra are not explicitly shown in FIG. 1. The extrapolated pseudo-damage spectra are then added up in the context of the superposition subprocess P6 to give rise to a superposed pseudo-damage spectrum 3. In other words, a single superposed pseudo-damage spectrum 3 is therefore formed from the plurality of measurement signals 1.1, 1.2, . . . 1.n, which were recorded on different route journeys of a test vehicle. This superposed pseudo-damage spectrum 3 is then fed to the test profile generation process P3.

In addition, the reference signal processing process P4 runs in the method shown in FIG. 1 in parallel with the pseudo-damage spectrum calculation process P1 and the extrapolation and superposition process P2. In the context of this reference signal processing process P4, a reference signal pseudo-damage spectrum is first calculated from a reference signal 5 by the spectrum calculation algorithm, which is also applied in the context of the pseudo-damage spectrum calculation process P1. For the sake of greater clarity, this reference signal pseudo-damage spectrum is not explicitly shown in FIG. 1. The reference signal pseudo-damage spectrum is then multiplied by the proportionality constant, which has already been applied in the extrapolation subprocess P5, so that an extrapolated reference signal pseudo-damage spectrum is created. This extrapolated reference signal pseudo-damage spectrum 6 is also fed to the test profile generation process P3.

In the context of the test profile generation process P3, the test profile 4 is then generated on the basis of the superposed pseudo-damage spectrum 3 and the extrapolated reference signal pseudo-damage spectrum 6. The test profile 4 can then be fed to a test specimen on a test rig, as a result of which the test specimen on the test rig undergoes a stress by being acted upon by the test profile 4 calculated in this manner, which stress corresponds to the stress arising from all preceding route journeys.

Although the generation of the extrapolated reference signal pseudo-damage spectrum 6 is shown in FIG. 1 as being generated in a separate reference signal processing process P4, other variants of the generation of the extrapolated reference signal pseudo-damage spectrum 6 are conceivable. For example, it is possible that the reference signal is generated directly in the context of the pseudo-damage spectrum calculation process P1 and the extrapolation and superposition process P2. In other words, for example, the reference signal processing process P4 can be carried out in part by the pseudo-damage spectrum calculation process P1 and in part by the extrapolation and superposition process P2.

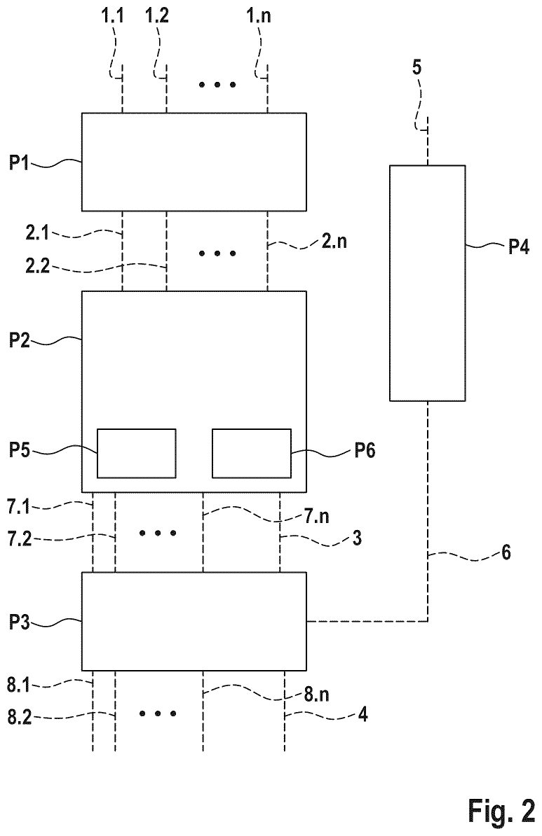

FIG. 2 shows a schematic view of a method according to further aspects of the invention in a second block diagram. The method in FIG. 2 is very similar to the method in FIG. 1. In contrast to the method shown in FIG. 1, in the method shown in FIG. 2, however, in addition to the superposed pseudo-damage spectrum 3, a plurality of extrapolated pseudo-damage spectra 7.1, 7.2, . . . , 7n is output by the extrapolation and superposition process P2. These extrapolated pseudo-damage spectra 7.1, 7.2, . . . , 7n are then also fed to the test profile generation process P3, which processes these such that a plurality of test profiles 8.1, 8.2, . . . , 8.n for individual routes is output on the output side of the test profile generation process P3 in addition to the test profile 4, which covers the damage on an entire route mix, as explained above. These test profiles 8.1, 8.2, . . . , 8n for individual routes are then available as secondary results of the method, in addition to the test profile 4 for the route mix (main result of the method) and can also be used in the test of the same product on test rigs. The distinguishing feature of the test profiles 8.1, 8.2, . . . , 8n is that they cover the damage on each individual route (for the total travel time on this route in the context of the route mix), but not on the route mix.

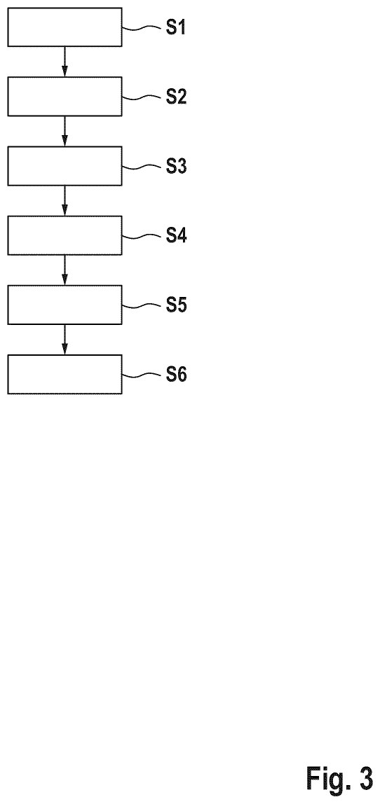

FIG. 3 shows a schematic view of a pseudo-damage spectrum calculation process P1 of the type that is used in a method according to the invention, as a block diagram. It is conceivable that the pseudo-damage spectrum calculation process in FIG. 3 includes a signal filter step S1, a classification step S2, a conversion step S3, a partial damage contribution calculation step S4, a cumulative damage calculation step S5, and a pseudo-damage spectrum formation step S6. In the context of the signal filter step S1, each measurement signal is filtered by a plurality of band passes, so that a plurality of filtered measurement signals is obtained. In the classification step S2, a load spectrum is formed from each filtered measurement signal by a classification. This is typically carried out by subdividing an entire amplitude range of each filtered measurement signal into classes, a number of the stress cycles preferably being determined for the amplitude of each class. In the conversion step S3, an amplitude, which optionally has an average value, of each stress cycle (a stress cycle may have an average value unequal to zero) is then initially converted into a damage-equivalent amplitude that does not have an average value. This conversion step is optional in certain embodiments. The conversion in the conversion step S3 is preferably carried out by a Haigh diagram. After the damage-equivalent amplitudes that do not have an average value are generated, these amplitudes that do not have an average value are sorted in ascending order. In the partial damage contribution calculation step S4, a partial damage contribution is calculated for each damage-equivalent amplitude that does not have an average value, preferably by utilizing an S-N curve. In the cumulative damage calculation step S5, the partial damage contributions are summed to obtain a cumulative damage for each filtered measurement signal, each cumulative damage being referred to as a pseudo-damage figure or “pseudo-damage value” of the particular filtered measurement signal. Finally, in the pseudo-damage spectrum formation step S6, the pseudo-damage spectra are formed from the pseudo-damage figures or “pseudo-damage values”. This typically takes place by representing the pseudo-damage figures as a function of the band pass central frequencies of the band passes.

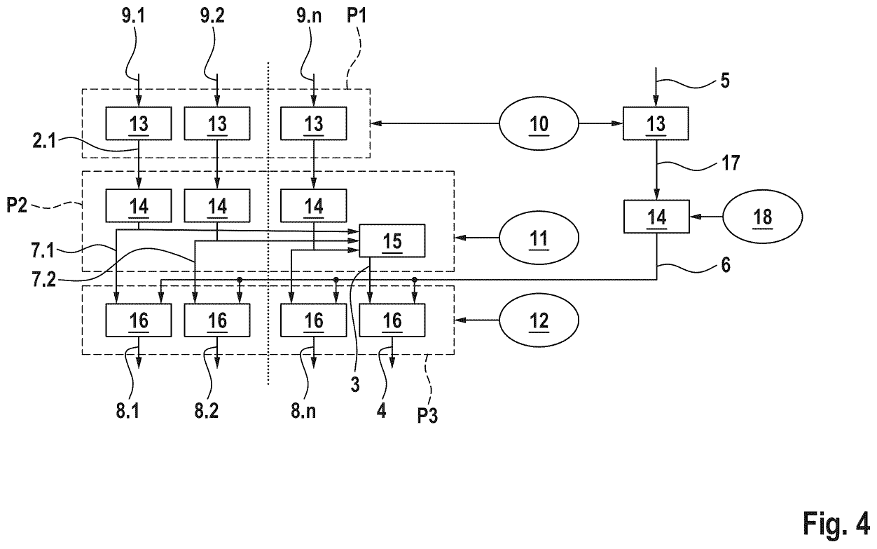

FIG. 4 shows a schematic view of a method according to further aspects of the invention. In particular, FIG. 4 shows how different computer-implemented components of the method according to the invention are interconnected and how the profile calculation is carried out in detail. FIG. 4 shows a pseudo-damage spectrum calculation process P1, an extrapolation and superposition process P2, and a test profile generation process P3. In particular, FIG. 4 shows a pseudo-damage spectrum calculation component 13, an extrapolation subcomponent 14, a superposition subcomponent 15, and a test profile generation component 16. In FIG. 4, some of these components 13, 14, 16 are shown more than once; therefore a corresponding instance of each component is discussed below. In each instance of an identical component 13, 14, 16, an identical calculation algorithm (FDDC or SPEX or PRGN algorithm—explained below) is implemented. The components 13, 14, 16 are active at different points in the method according to the invention, in particular during the processing of different signals and/or during the further processing of the characteristic values that have been intermediately calculated in one of the preceding steps. On the input side, n measurement files 9.1, 9.2, . . . , 9.n are made available to the method in FIG. 4. These measurement files 9.1, 9.2, . . . , 9.n arise typically due to the signal recording only on a small section, which is as representative as possible, of each of the n routes and each includes a measurement signal of an identical measurement variable (not explicitly shown in FIG. 4). The measurement files 9.1, 9.2, . . . , 9.n are each fed to an instance of the pseudo-damage spectrum calculation component 13. The pseudo-damage spectrum calculation component 13 outputs pseudo-damage spectra on the output side. In FIG. 4, only the first pseudo-damage spectrum 2.1 is provided with a reference character in order to avoid overloading the figure. The pseudo-damage spectra are then fed to the extrapolation and superposition process P2, where they are initially processed by the different instances of the extrapolation subcomponent 14 (one instance per pseudo-damage spectrum). Overall, there are, therefore, n instances. A plurality of extrapolated pseudo-damage spectra 7.1, 7.2, . . . , 7.n is then available on the output side of the extrapolation subcomponent 14. Only the first two extrapolated pseudo-damage spectra 7.1, 7.2 are provided with reference characters in this case as well, for the sake of greater clarity. The extrapolated pseudo-damage spectra 7.1, 7.2, . . . , 7.n are fed to the superposition subcomponent 15 and directly to the n instances of the test profile generation component 16. The superposition subcomponent 15 superposes the extrapolated pseudo-damage spectra 7.1, 7.2 (and all other available extrapolated pseudo-damage spectra that are not explicitly provided with reference characters, i.e., n spectra overall) and thus provides a superposed (and extrapolated) pseudo-damage spectrum 3 on the output side. This superposed pseudo-damage spectrum 3 is also fed to the test profile generation component 16. It therefore consists of a total of n+1 instances—including n instances of the test profile generation component 16 for the extrapolated pseudo-damage spectra 7.1, 7.2, . . . , 7.n, and one instance of the test profile generation component 16 for the superposed pseudo-damage spectrum 3.

In parallel with the processes P1, P2 and P3, an extrapolated reference signal pseudo-damage spectrum 6 is also generated in FIG. 4, which is also fed to all n+1 instances of the test profile generation component 16. This extrapolated reference signal pseudo-damage spectrum 6 is generated by first processing a (separately generated) reference signal 5 in one instance of the pseudo-damage spectrum calculation component 13, so that a reference signal pseudo-damage spectrum 17 is obtained. This reference signal pseudo-damage spectrum 17 is then fed to an instance of the extrapolation subcomponent 14, which generates the extrapolated reference signal pseudo-damage spectrum 6.

FIG. 4 also shows pseudo-damage calculation parameters 10, extrapolation and superposition calculation parameters 11, test profile calculation parameters 12, and reference signal extrapolation parameters 18. The pseudo-damage calculation parameters 10 typically include one or more definitions for band passes (for example, their cutoff frequencies, filter order, coverage of the individual filters, etc.), one or more parameters for rainflow countings, and/or an S-N curve. The pseudo-damage calculation parameters 10 are made available to the pseudo-damage spectrum calculation component 13. The extrapolation and superposition calculation parameters 11 typically include information regarding the full travel times on each of the routes that form the route mix, preferably in hours. The extrapolation and superposition calculation parameters 11 are transferred to the extrapolation and superposition process P2. The reference signal extrapolation parameters 18 typically include the information regarding the intended duration of the vibration testing of the product, preferably in hours. They are transferred to the extrapolation subcomponent 14 of the reference signal. The test profile calculation parameters 12 typically include a slope factor of the S-N curve and/or a safety factor and/or a test factor and/or a safety and test factor. The test profile calculation parameters 12 are transferred to the test profile generation component 16, in particular in the context of the test profile generation process P3.

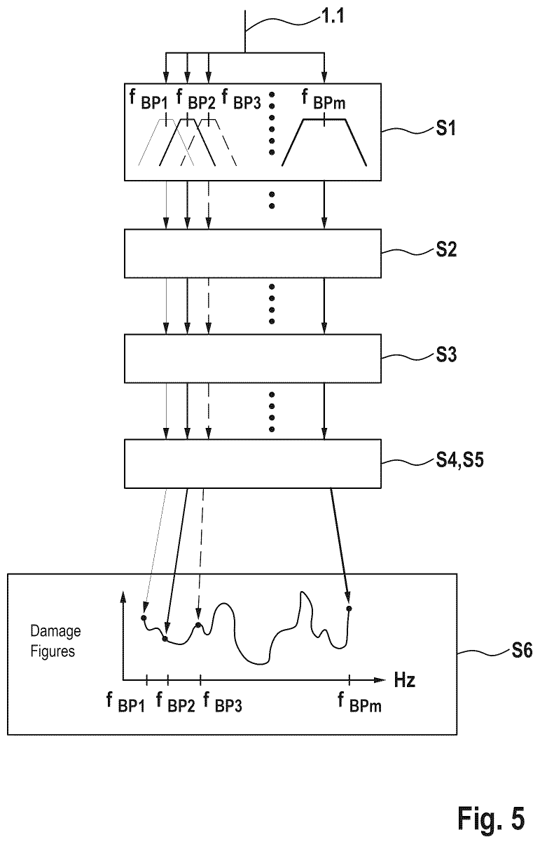

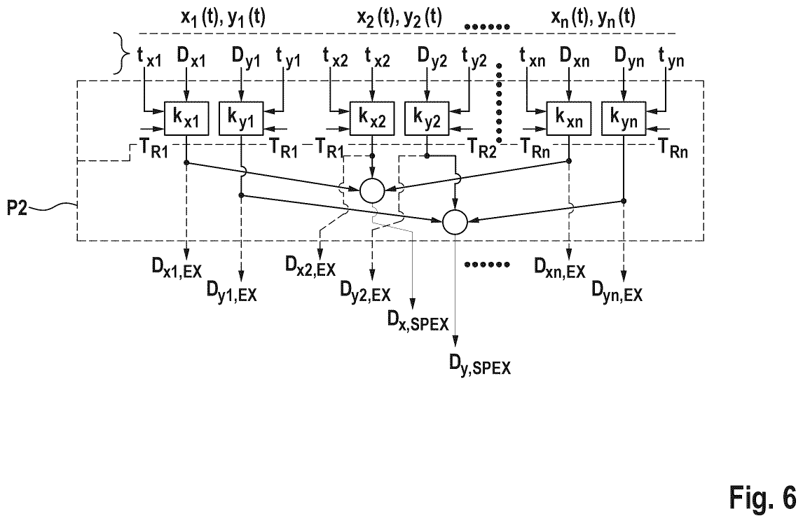

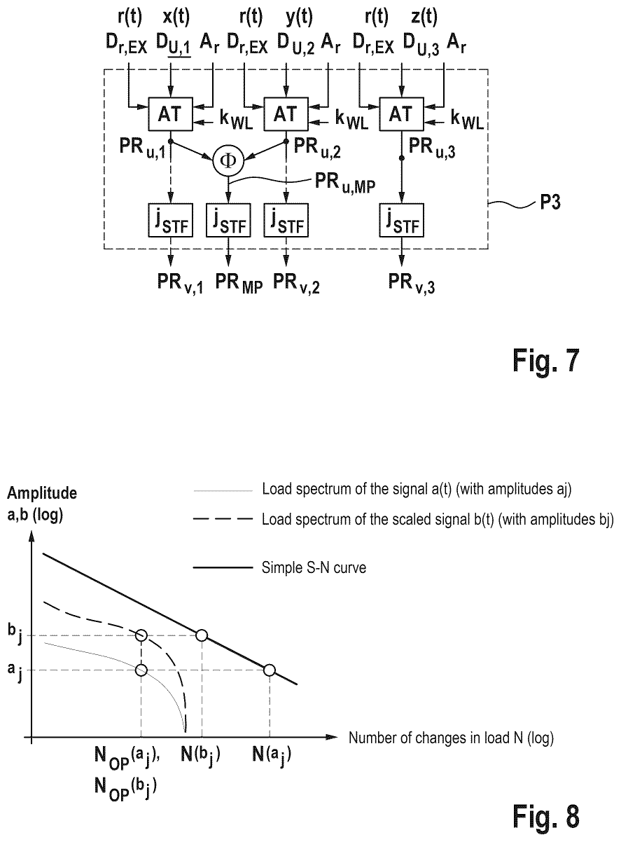

FIGS. 5-8 will be described in greater detail below. Generally, FIG. 5 shows a schematic view of a pseudo-damage spectrum calculation process of the type that is typically used in a method according to the invention. In particular, FIG. 5 shows how a plurality of damage figures or values that form a pseudo-damage spectrum is determined from a measurement signal 1.1. This is shown in FIG. 5 by a sequence of the steps: signal filter step S1, classification step S2, conversion step S3, jointly shown partial damage contribution calculation step S4 and cumulative damage calculation step S5, and pseudo-damage spectrum formation step S6. FIG. 6 shows a schematic view of an extrapolation and superposition process P2 for a plurality of measurement variables. FIG. 7 shows a schematic view of a test profile generation process P3 for a plurality of measurement variables. FIG. 8 shows an exemplary representation of load spectra and an S-N curve.

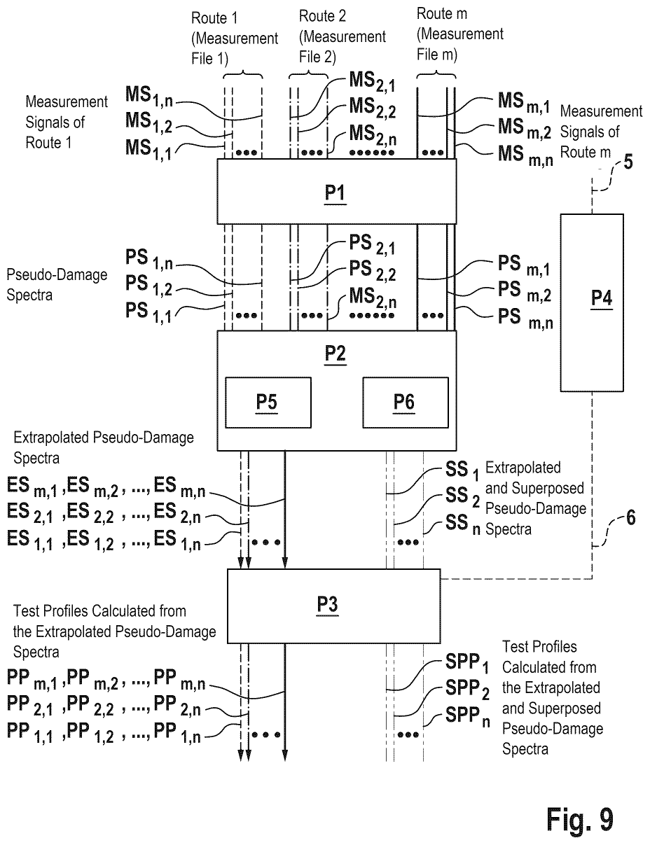

FIG. 9 shows a schematic view of a method according to even further aspects of the invention in a most complex block diagram. In contrast to the diagrams shown in FIGS. 1, 2 and 4, in the diagram shown in FIG. 9, multiple measurement signals, which have been measured on multiple routes, are processed, the signals belonging to various measurement variables. In this example, it is assumed that measurements have been carried out in a test vehicle (not shown) on a total of m travel routes and that n signals have been recorded on each route. As a result, a total of m*n measurement signals MS_{1,1}, MS_{1,2}, . . . , MS_{1,n}, MS_{2,1}, MS_{2,2}, . . . , MS_{2,n}, . . . , MS_{m,1}, MS_{m,2}, . . . , MS_{m,n} is fed to the method according to the invention, the signals (synchronously) measured on a route having been (digitally) stored in an identical measurement file. For example, n measurement signals MS_{2,1}, MS_{2,2}, . . . , MS_{2,n}, which have been recorded during the journey on the route 2, are located in measurement file 2. The number of measurement files m is therefore equal to the number of travel routes. Furthermore, in this example of the method, it is required that signals having the same last index have been obtained by recording an identical measurement variable on different routes, for example, the signals MS_{1,1}, MS_{2,1}, . . . , MS_{m,1} by recording the measurement variable 1, the signals MS_{1,2}, MS_{2,1}, . . . , MS_{m,2} by recording the measurement variable 2, etc. In contrast to the examples of the method in FIGS. 1, 2 and 4, this results—inter alia—in the following particularities:
in the pseudo-damage spectrum calculation process P1, m*m, rather than n, pseudo-damage spectra PS_{1,1}, PS_{1,2}, . . . , PS_{1,n}, PS_{2,1}, PS_{2,2}, . . . , PS_{2,n}, . . . , PS_{m,1}, PS_{m,2}, . . . , PS_{m,n} are calculated from measurement signals,
in the extrapolation subprocess P5 of the extrapolation and superposition process P2, m*m, rather than n, extrapolated pseudo-damage spectra ES_{1,1}, ES_{1,2}, . . . , ES_{1,n}, ES_{2,1}, ES_{2,2}, . . . , ES_{2,n}, . . . , ES_{m,1}, ES_{m,2}, . . . , ES_{m,n} are calculated from these pseudo-damage spectra; each of these describes the damage for a measuring point and direction on the considered component (product) on each individual route (but not on a complete route mix),
in the test profile generation process P3, m*m test profiles PP_{1,1}, PP_{1,2}, . . . , PP_{1,n}, PP_{2,1}, PP_{2,2}, . . . , PP_{2,n}, . . . , PP_{m,1}, PP_{m,2}, . . . , PP_{m,n} are calculated from these extrapolated pseudo-damage spectra; each of these covers the damage for a measuring point and direction on the considered component on each individual route (but not on a complete route mix) and is suitable for carrying out vibration testing of the component with the profile control at this point, with the oscillation introduced in this direction; in such a test, this damage, which is equivalent to the corresponding route, is applied at the corresponding point of the component and in the corresponding direction,
in the superposition subprocess P6 of the extrapolation and superposition process P2, a plurality of, rather than one, superposed (and extrapolated) pseudo-damage spectra SS₁, SS₂, . . . , SSₙ is now calculated, specifically one pseudo-damage spectrum per measurement variable; each spectrum of this type describes the damage to the considered component on a complete route mix for the corresponding measuring point (i.e., the location of the sensor) and measurement direction,
consequently, in the next step in the test profile generation process P3—inter alia—n profiles SPP₁, SPP₂, . . . , SPPₙ are calculated from these n pseudo-damage spectra SS₁, SS₂, . . . , SSₙ. They all cover the damage to the component on the complete route mix—each profile for its measuring point and direction on the component, and are suitable for carrying out vibration testing of the considered component with the profile control at the corresponding point (the location of the sensor), with the introduction of the oscillations according to the profile in the corresponding direction. In such a test, this damage, which is equivalent to the complete route mix, is applied at the certain point on the component and in the corresponding direction.

In this example of the method, the reference signal processing process P4 remains identical to the above-described embodiments in FIGS. 1 and 2.

In the following, some examples of the invention are described in a particularly detailed manner—inter alia—with reference to FIGS. 4 through 9. Numbers in brackets are still to be understood as references to the list of references at the end of the description. Numbers or lower-case letters in parentheses are to be understood in the following as references to the corresponding mathematical formulas that are labeled using these numbers or lower-case letters in parentheses.

In one particular example, a method according to the invention (the “ASPEN method” or the “ASPEN RoMi method”) is based on the calculation and the equivalence of the damage figures; it therefore belongs to the group of the damage-based methods. It is calculated by a following approach, which is known in the context of durability:
forming a load spectrum from the considered time variable (by a classification or counting method), and
converting the load spectrum into a damage figure by the hypothesis of material fatigue according to Wöhler (described mathematically using an S-N curve) and by the hypothesis of a linear accumulation of damage (Palmgren-Miner rule).

At this point it is also pointed out that the S-N curve used to calculate the damage figures is based on an assumption in most practical cases and is not necessarily true for the considered measurement variable and/or the stress state. It is, therefore, fictitious. The damage figures calculated in this way are therefore not meaningful with respect to an absolute point of failure or a remaining service life of the considered component and, for this reason, they are referred to as “pseudo-damage figures” (abbreviated in the following as “PSZ”). However, the PSZ is meaningful for comparative damage-based calculations and analyses, as in the ASPEN method.

On the basis of the PSZ, a novel, fundamental characteristic value—the pseudo-damage spectrum (PSS)—is introduced in the ASPEN method. It describes the dependence of the PSZ of an oscillating time signal on the oscillation frequency. It is explained in detail below in the subsection “Pseudo-damage spectra.”

The basic idea of the ASPEN RoMi method consists of the following:

The test profile created for the vibration testing of a component is intended to computationally ensure the equality of the two following PSS at every oscillation frequency:
of the PSS that is obtained in the traveled route mix, after extrapolation and, optionally, superposition onto the required component service life, and
of the PSS that the component will undergo in vibration testing with the created profile for the established testing time in a spatial axis.

In this sense, the ASPEN RoMi method therefore delivers damage-equivalent test profiles.

The damage equivalence applies individually for each considered point at which signals for creating the profile were measured—for example, on the component or on the component mounts.

The ASPEN RoMi method includes three calculation modules, as shown in FIG. 4:
an FDDC (Frequency Dependent Damage Calculation) module, which is also referred to as a pseudo-damage spectrum calculation component 13,
an SPEX (SuperPosition and EXtrapolation) module, which is also referred to as an extrapolation and superposition component, which includes an extrapolation subcomponent 14 and a superposition subcomponent 15, and
a PRGN (PRofile GeNeration) module, which is also referred to as test profile generation component 16.

In these, acceleration signals are measured (using the ASPEN method, profiles can be created for each oscillating measurement variable; for the sake of simplicity, acceleration will be discussed as the input variable for calculating the profile) during the test journeys on the routes, and a specifically generated time signal—the reference signal—is evaluated. Therefore, to calculate the profile by the method, two modules of three—FDDC and SPEX—are carried out twice; see FIG. 4. The evaluation of the measurement signals from the route journeys and the evaluation of the reference signal are carried out in the same way.

Typical calculation steps of the method are:
calculating a PSS for each individual signal (FDDC module),
extrapolation and superposition of the individual PSS to form a PSS (SPEX module), and
generating a test profile (PRGN module).

For the sake of simplicity, the approach to creating the profile using the ASPEN RoMi method from measured data of only one measurement variable is explained first. This results in some limitations; for example, it excludes the profile creation for multi-point control, which is discussed later in the individual description of the SPEX and PRGN modules.

The following terms from measurement technology are used in the description of the method:
A measurement variable is, according to DIN 1319-1, the temporally variable, physical variable to be measured (for example, acceleration); it always relates to a certain measuring point and measurement direction (since oscillations are direction-dependent). It is referred to as β(t) further on in the document
A measuring point (point of measurement) is a spatially delimited, local point on the component or on the component mounts that is selected for detecting a measurement variable. For this purpose, a sensor (for example, acceleration sensor) is mounted at this point.
The measurement signal is the result of the measurement of a measurement variable; it is generated by the measuring system during the journey on a section (measurement section) of a route after triggering and stopping the measurement once, and it is present in digital form. A measurement signal of the measurement variable γ(t), detected on such a measurement section during the journey on the route i, is referred to as γᵢ(t).
A measurement file is a file with measurement signals of all measurement variables that are synchronously detected by the measuring system during the journey on a measurement section of a route, digitized, and stored on a data carrier. The measurement file has a name and the measurement signals appear there, digitally stored, under the name of the particular measurement variable.

It is assumed that, for the vibration release of a component (intended for operation in a motor vehicle), a route mix consisting of n different design-relevant routes has been defined. The travel time T_{RM} on the entire route mix is composed of the travel times on the individual routes T_{Ri} (i=1, . . . , n). The component under consideration is intended to achieve its full service life T_{LD} by the vehicles traveling (optionally cyclically) on this route mix.

This means

$${T}_{L D} = {T}_{R M} = {\sum }_{i = 1}^{n} {T}_{R i} \qquad ( 3.1 )$$

Furthermore, tests (for example, in a test vehicle) were carried out on each section of each route to acquire the data, and a variable γ (for example, acceleration in one direction) was measured at a point on the considered component. As a result, there is one acceleration signal γᵢ(t) for each measurement interval (measurement section) of duration t_{γi} on each route i (i=1, . . . , n). It is also assumed that it has been stored in a separate measurement file in each case, so that there is a measurement file having this signal for each traveled route (this assumption applies for the description of the ASPEN RoMi method at all points of this description, except for the following “Further explanations” at the end of the description, in which the extrapolation and the superposition of the PSS for the case of multiple measurement files per traveled route are discussed).

A damage-equivalent test profile is to be derived from these n signals (as input data) using the ASPEN RoMi method. The PSS are calculated for an assumed (fictitious) S-N curve. Mathematically, it is described by the parameters N_{A}, a_{A} (support point A) and k_{WL} (slope coefficient) according to the formula (3.8). Since it has an identical slope coefficient k_{WL} at all amplitudes a, it proceeds without a bend, in particular also without a fatigue strength range. It is referred to further on in the document as a simple S-N curve. As is known, the mathematical description of the component failure by an S-N curve applies only for fatigue [1, 15]; this is also a requirement for creating a profile in the ASPEN method.

The test frequency range is from fᵤₙₜ, . . . , f_{ob}.

The profile creation for the considered case is described below in the steps a) through g). In FIG. 4, they are illustrated as follows: the calculation steps a) through c) are characterized by thick branches with arrows in the left part of the diagram, d) through f) being characterized by thin branches in the right part of the diagram; for the calculation step g), these branches are finally combined in the PRGN module.

### a) Calculating the PSS for Route Journeys

First, a PSS D_{γi}(f) is calculated for each acceleration signal γᵢ(t), measured on each section of the route i=1, . . . , n, in the defined test frequency range f=fᵤₙₜ, . . . , f_{ob}. For this purpose, a set of linear band passes (for example, of the Butterworth type), each having a narrow pass-range, is defined. The pass-ranges of the adjacent band pass filters adjoin one another such that they neither overlap nor do holes form between them, and they cover the entire test frequency range. Each input signal γᵢ(t) is filtered with these.

A load spectrum is then formed from each band pass-filtered signal by a counting method. A classification method is preferred that delivers not only the amplitudes, but also average values of the stress cycles (two-parameter load spectrum). In the ASPEN method, rainflow counting, which delivers rainflow collectives in the form of rainflow matrices, is used for the classification.

Each such two-parameter load spectrum is then transferred, by an amplitude transformation according to Haigh [15] (Haigh diagram), into a damage-equivalent single-parameter amplitude collective that does not have an average value. From this, a PSZ is then calculated by a simple S-N curve and a linear damage accumulation hypothesis (for example, in the form “elementary Miner” or using “Miner's rule”).

Furthermore, each PSZ calculated in this way is associated with the central frequency of the pass-range of the corresponding band pass. The juxtaposition of these PSZ in the ascending order of the filter central frequencies finally yields the PSS D_{γi}(f) of the signal γᵢ(t).

All these calculations are carried out in the FDDC module; see n calculation blocks FDDC (also referred to as pseudo-damage spectrum calculation component 13) in the left part of the diagram in FIG. 4. The FDDC algorithm for calculating a PSS from a time signal is described in greater detail further below.

### b) Extrapolation of the PSS for Route Journeys

These individual PSS D_{γi}(f) (i=1, . . . , n) apply for the signal measuring time t_{γi} on the measurement section of the corresponding route. In order to keep the testing and measuring complexity of the data acquisition as low as possible, t_{γi} is generally considerably smaller than the actual travel time T_{Ri} that the vehicle will spend on this route (within the required service life T_{LD}): t_{γi}<<T_{Ri}. In order to obtain the PSS, which covers the total travel time T_{Ri} on the route i, the PSS D_{γi}(f) calculated in the preceding step is multiplied by a factor k_{γi}:

$${D}_{γ i , E X} = {k}_{γ i} \times {D}_{γ i} \qquad ( 3.2 )$$

The proportionality constant k_{γi} is calculated as the ratio of the two above-described travel times:

$${k}_{γ i} = {T}_{R i} / {t}_{γ i} \qquad ( 3.3 )$$

This procedure is called the extrapolation of the PSS. It is based on a method for extrapolating the damage figures of the PSZ, which is known and established in the context of durability, and is now applied to the PSS. The proportionality constant k_{γi} is known as an extrapolation factor [1, 15]. The extrapolation of the PSS is carried out in the SPEX module; see n calculation blocks 14 (also referred to as extrapolation subcomponent 14) in the left part of the diagram in FIG. 4.

### c) Superposition of the PSS for Route Journeys

The extrapolated PSS D_{γi,EX}(f), calculated in the preceding step according to (3.2), represent the degree of damage to the component during travel only on each individual route i (for the corresponding duration T_{Ri}). It is assumed, however, that the component is designed for operation on the entire route mix. Therefore, the overall damage that the component will undergo in the complete mix consisting of n different routes must be determined. Since the travel time on the route mix is composed of travel times T_{Ri} on individual routes (see relationship (3.1)), the degree of damage of the route mix can also be calculated as the sum of the degree of damage of the individual routes. Therefore, the individual extrapolated PSS D_{γi,EX}(f) can then be added up to form one overall PSS D_{γ,SPEX}(f):

$${D}_{γ , SPEX} = {\sum }_{i = 1}^{n} {D}_{γ i , E X} \qquad ( 3.4 )$$

This procedure is called the superposition of the PSS. It is also based on the method, which is known in the context of durability, of superposing the damage figures or the PSZ of individual operating states (here: routes) to form the overall damage.

The superposed PSS D_{γ,SPEX}(f) applies for the travel time T_{RM} on the total route mix; the travel times T_{R1}, T_{R2}, . . . , T_{Rn}. are distributed with respect to one another according to (3.1) on n individual routes of this mix. Since it is assumed that T_{LD}.=T_{RM}, the superposed PSS D_{γ,SPEX}(f) simultaneously represents the degree of damage to the component for its entire intended service life T_{LD}. The superposition of the PSS is also carried out in the SPEX module, in particular in the superposition subcomponent 16; see FIG. 4.

### d) Generating the Reference Signal

The question then arises regarding the determination of the damage-equivalent level of the test profile. According to the formulation of the ASPEN RoMi method, this means: in a vibration test having the duration T_{VT}, a damage that is identical to the damage that the component sustained in the route mix having the duration T_{RM} is supposed to be imparted to the component with the profile of this level. This damage was computationally determined in the steps a)-c) and is expressed by the extrapolated and superposed PSS D_{γ,SPEX}(f). The problem of converting a PSS into damage-equivalent profile amplitudes is that the ratio between these two variables must be known, wherein it depends—inter alia—on the established type of vibration testing (sweep or noise).

In order to solve this problem, according to the invention, a time signal r(t) that is appropriate for the type of vibration testing is automatically generated, and its damage for the intended duration of the vibration testing T_{VT} is calculated. While r(t) was referred to as the reference signal, it is nothing more than an actuation signal that would generate a vibration test system during the conversion of the test profile of a certain type (sweep or noise profile). It can be generated, for example, as a real vibration signal on a vibration test rig, equipped with a suitable control system, and recorded using a suitable measuring system. An alternative possibility is provided by many PC-supported signal processing tools, for example, Matlab, Famos, Labview. In its surroundings, the reference signal can be generated as a fictitious digital signal (for example, for creating the noise profiles by an algorithm for generating random numbers). This is a time-saving and affordable possibility, since it requires neither a vibration test rig for generating vibrations nor a measuring system for recording the signals.

The level of the reference signal can be arbitrarily selected; however, it must be constant over the frequency f in the entire test frequency range f=fᵤₙₜ, . . . , f_{ob} (according to the concept of the ASPEN method). The level means the amplitude frequency curve (AFV) S_{Ref} when r(t) is a sweep signal (for a sweep test) or the PSD PSD_{Ref} when r(t) is a stochastic signal (or a noise test). It is therefore desired that S_{Ref}=const, PSD_{Ref}=const. In the latter case, this condition means that r(t) in the test frequency range f=fᵤₙₜ, . . . , f_{ob} is generated as a white noise.

The approach to generating such a signal, together with the next steps e) and f), was referred to as the concept of the reference signal. It is described in detail further below.

### e) Calculating the PSS of the Reference Signal

Once the reference signal r(t) has been generated in the above-described manner, its PSS is calculated. For this purpose, the FDDC algorithm is carried out once more; see the computing block 13 in the right part of FIG. 4. In order for the ASPEN method to function correctly, the same calculation parameters must be used as for the calculation of the PSS of the signals from the route mix journeys (in step a)). In particular, this applies to the configuration of the band pass filters, and to the classification parameters and the S-N curve parameters.

The calculated PSS is referred to as Dᵣ(f); it applies for the duration tᵣ of the generated reference signal r(t).

### f) Extrapolation of the PSS of the Reference Signal

To calculate the degree of damage that occurs in a vibration test having the established duration T_{VT}, the PSS of the reference signal Dᵣ(f) calculated in the preceding step must be extrapolated to this duration. This takes place in the same way as the extrapolation of the PSS for route journeys (see step b)), specifically by multiplying Dᵣ(f) by the corresponding extrapolation factor.

$${D}_{r , EX} ( f ) = {k}_{r} \times {D}_{r} ( f ) \qquad ( 3.5 )$$

It is calculated as follows:

$${k}_{r} = {T}_{VT} / {t}_{r} \qquad ( 3.6 )$$

The extrapolation of the PSS of the reference signal is carried out in the SPEX module 14, similarly to that of the PSS from route measurements; the SPEX module 14 is carried out once more for this purpose; see computing block 14 (also referred to as extrapolation subcomponent 14) in the right part of FIG. 4.

### g) Calculating the Level of the Test Profile

Then, the two extents of damage are present—the superposed PSS from the route mix D_{γ,SPEX}(f), and the extrapolated PSS of the reference signal D_{r,EX}(f). In addition, it is then also known that the component damage D_{r,EX}(f) in a vibration test with the sweep excitation (computationally) arises due to the amplitude S_{Ref}, or with the noise excitation due to the PSD PSD_{Ref} when the two tests are each of the duration T_{VT}. This makes it possible to convert S_{Ref} or PSD_{Ref} into another amplitude S_{U} or into another PSD value PSD_{U}, respectively, which will lead to the damage D_{γ,SPEX}(f). This damage-equivalent conversion is defined, depending on the profile type, by formula (3.17) (for sweep profile), or formula (3.16) (for noise profile) (therein D_{Ref}(f)=D_{r,EX}(f) and D_{U}(f)=D_{γ,SPEX}(f). The two relationships (3.16) and (3.17) were independently developed and referred to as ASPEN transformation (AT).

For this conversion of the PSS into the profile amplitudes, the PRGN module (also referred to as test profile generation component 16) is carried out; see FIG. 4. The conversion is carried out separately for each frequency f in the defined test frequency range f=fᵤₙₜ, . . . , f_{ob}.

A sweep profile or noise profile calculated in this manner forms the result of the method. It is suitable for the damage-equivalent vibration testing of the considered component with the profile control at the point at which the acceleration variable x(t) was measured in the route journeys (single-point control).

Particularities or additions with respect to the above-described procedure a)-g):
It is used separately to create the profiles in each spatial axis. Signals γᵢ(t) measured in the corresponding spatial direction are used for this purpose. The method is therefore suitable primarily for vibration testing on test rigs with the possibility of generating the oscillations in only one spatial axis (for example, on electrodynamic shaker rigs). When a vibration test device permits oscillations to be generated in three spatial directions simultaneously (as is typically the case, for example, on servohydraulic test rigs), profiles can be initially created separately from one another for each direction according to the above-described procedure. Then, during the test, vibrations generated by the vibration control system according to these profiles can be introduced into the test specimen simultaneously in the mutually perpendicular directions.
The reference signal can also be a multi-sweep (for creating a multi-sweep test profile) or a sinusoidal wave having a fixed frequency (for creating a profile with which a dwell time test can be carried out).
Excitation and response profiles are created according to this uniform procedure; it differentiates only the use of the signals of various measuring points—on the component itself (for creating a response profile) or at the component mounts (for creating an excitation profile). All these signals must be recorded synchronously on route mix journeys; the excitation profiles are generally used for the test rig control, the response profiles are used to limit the amplitudes of the component response.
For the case in which signals of multiple measuring points are present and are supposed to be evaluated jointly to create the profile, see the subsection “Multiple measuring points” directly below.
Except for the entire route mix, according to this procedure, profiles are also created for covering the component damage only on individual routes; for this purpose, in the AT (3.16), (3.17), rather than D_{γ,SPEX}(f), the corresponding extrapolated PSS D_{γi,EX}(f) is used (they were calculated normally for each route in step b); such profiles cover the component stressing for the travel time T_{Ri} on each route.

### Multiple Measuring Points:

Previously, the method was described for a simpler case in which test profiles were derived only from signals of a measurement variable (defined for a measuring point). The procedure is also applicable in a slightly modified form when measurement signals have been detected on route journeys at multiple points (for example, on the component and/or on the component mounts) in an identical direction, and these are supposed to be evaluated jointly to create a profile. The difference in the method relates only to the PRGN algorithm and only to the case of a multi-point control. This case is discussed further below.

### Pseudo-Damage Spectra (PSS):

The term pseudo-damage spectrum was introduced in the ASPEN method for the characteristic value that expresses the dependence of the PSZ on the central frequency of each narrow-band band pass.

PSS is a fundamental, central characteristic value of the ASPEN method. Considering an oscillating time signal, the PSS represents a distribution of the PSZ of its individual harmonic components with respect to the oscillation frequency. Since the dependence of a function on the frequency has a physical analogy to the term spectrum (as calculated from a time signal in a classical manner using the Fourier transform [14]), the word spectrum is used in the term PSS.

According to the physical content, PSS is similar to the characteristic value FDS (Fatigue Damage Spectrum). FDS is widely used to analyze the fatigue behavior of the components and to synthesize damage-equivalent profiles using the damage- and model-based methods that are based on the model of a linear, weakly damped SDOF [6-9]. FDS therefore absolutely requires the model of an SDOF of this type (with the acceleration of the base point as the input variable, and the relative displacement amplitude of the SDOF as the vibration response). The calculation of a PSS in the ASPEN method is not bound, however, to a mathematical model of the component, for which the test profile is intended to be created. This is the difference between FDS and PSS.

Since a PSS consists of individual PSZ, a PSS is also not real damage, but rather fictitious damage. A PSS is therefore also not suitable for an absolute prediction of service life. The PSS can be meaningfully interpreted only by comparing two PSS with one another, which have been calculated, for example, for two different time signals. Specifically, in the following sense: “at a certain vibration frequency, the stress on a component through one time sequence is more damaging (more severe) than through the other.” However, the calculation of the two PSS for this purpose must always be carried out under the same conditions. This applies to all calculation parameters of the PSS, above all to the parameters of the S-N curve and the width of the pass-range of the band passes. If (in rare cases) an accurate S-N curve for the considered component, material, the measurement variable, and the load case is actually known, then it can be adjusted and used in the ASPEN method. As a result, the calculated damage figures are no longer fictitious and they can (optionally after extrapolation and superposition) provide a statement regarding an actual service life of the component. In this case, this is not the PSZ and the PSS, but rather real damage figures and damage spectra.

Each PSS D(f) is calculated from a time signal x(t) of a certain duration tₓ, and applies only for this duration. It must be output together with the PSS. Without this detail, the time for which the (pseudo-) damage was accumulated at each frequency is not known.

A PSS can be used not only to synthesize the damage-equivalent test profiles, but also, for example, to compare the severity of two profiles of different types (for example, of a sweep profile with a noise profile).

### Calculation of the PSS (FDDC Algorithm):

The FDDC model is used to calculate the PSS from time signals, measured during the route journeys, and from the reference signal. For each signal x(t) of the duration tₓ, regardless of it origin, a PSS D(f) is calculated, specifically according to an identical algorithm described below. In the notations above, these are x(t)=γᵢ(t), tₓ=t_{γi} (i=1, . . . , n).

The FDDC algorithm includes the following; see FIG. 5:

a) Filtering the Signal x(t) with a Set of Multiple Narrow Band-Pass Filters in the Signal Filter Step S1:

First, the band pass filter is configured in the selected test frequency range f=fᵤₙₜ, . . . , f_{ob}. They can be of any type, for example, Butterworth, Bessel, Tschebyschew, etc. In order to achieve a sufficiently high resolution of the profile curve to be calculated across the frequency, at least 500 . . . 1000 band passes are configured in a frequency range of the type defined for vibration testing of vehicle equipment typically from fᵤₙₜ=10 Hz to f_{ob}=2 kHz. As a result, the pass-range of the band passes is only a few Hertz, such that they can be referred to as narrow-band. Depending on the selection of the parameters of the filter synthesis (cutoff frequencies and the step of changing the central frequencies), the band passes can have an identically wide pass-range or a variable pass-range. Regardless thereof, these parameters must be selected such that the pass-ranges of the adjacent filters neither overlap nor have holes therebetween. With this in mind, the filter order and filter type (conventional or “zero-phase” filtering) can be freely selected.

The filtering of an input signal x(t) with the set of m such band passes yields m output signals. The output signal of the j^{th} band pass is referred to as x_{BP,j}(t) (j=1, . . . , m).

### b) Classifying the Band-Pass-Filtered Signals in the Classification Step S2:

Then, a load spectrum is formed from the output signal x_{BP,j}(t) of each filter by a classification. For this purpose, the total amplitude range of x_{BP,j} is divided into l classes, and the number of cycles N_{OP,i} is determined for the amplitude aⱼ of each class i (i=1, . . . , l) by a counting or classification method. Various classification methods known from the context of durability can be used for this purpose; preferably, however, those which also enable determination, apart from the amplitude aᵢ, of an average value mᵢ for each cycle, for example, the rainflow counting method. Therefore, a load spectrum calculated in this way N_{OP}=N(a, m) describes the frequency of the occurrence of the cycles having certain amplitudes a and average values m in the considered time signal x_{BP,j}(t).

For the aforementioned reason, the rainflow classification is used in the ASPEN method to form the load spectra; it yields rainflow collectives in the form of rainflow matrices. They are represented in the coordinates “average value/amplitude,” i.e., each counted stress cycle is characterized by its amplitude (half a span) and the average value (therefore, for example, for an acceleration signal having the ordinate unit m/s², the two abscissa of the rainflow matrix are also scaled in m/s²; the ordinate contains the number of closed stress cycles). Any residual that may be present is added to the matrix after the conclusion of the rainflow counting.

In such a way, a rainflow matrix is therefore calculated for each filtered signal x_{BP,j}.

c) Conversion into Damage-Equivalent Amplitudes that do not have an Average Value in the Conversion Step S3:

In the rainflow matrix, as described above, each stress cycle has a corresponding amplitude aᵢ and an average value mᵢ. Only the amplitude is used, however, to determine the degree of damage of a cycle by the Wöhler approach known in the context of durability (see the next section d)); as is known, this approach does not take the average value of a stress cycle into account. Since it can influence—inter alia—the degree of damage of a stress cycle, the amplitude aᵢ—which may have an average value—of each stress cycle of the rainflow matrix is initially converted into a “damage-equivalent amplitude without an average value” (SMA) a_{SM,i}. This is carried out by the method according to Haigh [15] (the Haigh diagram), which is also known in the context of durability. Then, these converted amplitudes are sorted in an ascending order; this yields a dependence on the number of stress cycles (it remains unchanged in the transformation according to Haigh) in the rainflow matrix of the SMA N_{OP}=N(a_{SM}).

### d) Calculating the Partial Damage Contributions in the Partial Damage Contribution Calculation Step S4:

Then, the extent of the damage is calculated for each SMA a_{SM}, of the load spectrum having/classes (i=1, . . . , l), formed from each filtered signal x_{BP,j}.

$${D}_{i} = \frac{{N}_{OP , i}}{{N}_{i}} \qquad ( 3.7 )$$

wherein Nᵢ—the number of stress cycles that, at the load amplitude a_{SM,i}, result in a failure of the component.

The parameter Nᵢ is determined on the basis of a simple S-N curve; this is described by a following equation:

$${( \frac{{a}_{SM , i}}{{a}_{A}} )}^{{k}_{WL}} = \frac{{N}_{A}}{{N}_{i}} \qquad ( 3.8 )$$

wherein N_{A}, a_{A}—the number of oscillation cycles that, at a certain load amplitude a_{A}, result in component failure, and this amplitude (such a point A having the coordinates (N_{A}, a_{A})) is known as a support point of the S-N curve,
k_{WL}—the slope coefficient (slope factor) of the S-N curve.

In order to be able to carry out the calculation according to (3.8), the parameters k_{WL}, N_{A}, a_{A} of the S-N curve are initially established. An S-N curve in the form (3.8) absolutely must be used in the ASPEN method.

### e) Calculating the Cumulative Damage for the Output Signal of Each Band Pass; Cumulative Damage Calculation Step S5:

Once the partial damage contributions Dᵢ for each amplitude a_{SM,i} of each load spectrum have been determined according to (3.7), the resultant damage D_{GS}, which arises by acting on the component with l loads having various amplitudes a_{SM}, (i=1, . . . , l), is calculated by applying the linear damage accumulation hypothesis (Palmgren-Miner rule) as follows:

$${D}_{GS} = {\sum }_{i = 1}^{I} {D}_{i} \qquad ( 3.9 )$$

This yields the cumulative damage of the output signal x_{BP,j}(t) of each j^{th} band pass filter. Since the S-N curve used for the calculation is fictitious in most cases (see above), D_{GS} is the PSZ of the time sequence x_{BP,j}(t).

### f) Forming the PSS in the Pseudo-Damage Spectrum Formation Step S6:

The PSZ, calculated for output signals of all m band passes that were defined in the current test frequency range f=fᵤₙₜ, . . . , f_{ob}, are then associated with the central frequency f_{BP} of the pass-range of the particular band pass; the representation of the PSZ as a function of the particular filter central frequency yields a PSS D(f) (f=f_{BP}).

It is mentioned here again that each measurement signal in the FDDC module (also referred to as pseudo-damage spectrum calculation component 13) is evaluated according to this same algorithm regardless of the signal of another measuring point or an identical point, measured on another route. Therefore, when, for example, multiple variables (signals of multiple measuring points) have been recorded during the route journeys, nothing is changed in the FDDC algorithm.

### Extrapolation and Superposition of the PSS (SPEX Algorithm):

A PSS D_{γi}(f), calculated using the FDDC algorithm from a time signal γᵢ(t) recorded during a journey on the route i, is related only to its measuring time t_{γi}. It is generally considerably shorter than the full travel time T_{Ri} on the corresponding route: t_{γi}<<T_{Ri}. In the vibration test with a test profile, however, a full service life of the component must be secured. According to (3.1), the full service life is a total of the travel times T_{Ri} on n individual routes (i=1, . . . , n). Therefore, all PSS calculated using the FDDC algorithm must be extrapolated and optionally superposed in the next step. The SPEX algorithm was developed for this purpose.

The extrapolation and the superposition of the PSS in the ASPEN RoMi method is based on a procedure known in the context of durability, with which (real or fictitious) damage figures are extrapolated and superposed. The extrapolation consists of multiplying the damage figures, determined from tests on individual routes, by correspondingly calculated extrapolation factors; superposition consists of adding the extrapolated damage figures to one another. Since each ordinate of a PSS is a PSZ, this method can be transferred, unchanged, to the extrapolation and the superposition of the PSS.

In the explanations of the SPEX algorithm below, it is assumed, as it was previously, that one measurement file is present for each traveled route. The extrapolation and the superposition of the PSS for the case of multiple measurement files per route is described further below.

In order to carry out the extrapolation and superposition algorithm in the ASPEN RoMi method, only the travel times T_{Ri} on n individual routes need to be indicated (i=1, . . . , n).

In the block diagram of the ASPEN RoMi method in FIG. 4, the extrapolation of the PSS is illustrated by the n computing blocks 14 (in the left part of the diagram); the superposition is illustrated by the block 15.

### Extrapolation of the PSS for Route Journeys:

The extrapolation of the PSS is described using the formula (3.2). It is a pure multiplication procedure of a PSS D_{γi}(f) by a constant k_{γi}, referred to as the extrapolation factor. It is calculated as the ratio T_{Ri} of the full travel time on a route i to the (individual) measuring time t_{γi} of the signal γᵢ(t) on the measurement section of this route according to (3.3). Since k_{γi} is identical for all frequencies f of a PSS, the extrapolated PSS D_{γi,EX}(f) is always a scaled copy of D_{γi}(f).

Physically, this extrapolation method corresponds to a following—idealized—interpretation: the journey on the measured section of a route i is repeated by the test vehicle k_{γi} times. In every repeat journey, exactly the same PSS D_{γi}(f) arises for the considered measurement signal γᵢ(t). At the end of all these repeated journeys, the established travel time T_{Ri} and the damage corresponding thereto, expressed by the PSS D_{γi,EX}(f), is reached for the considered measurement signal γᵢ(t).

The extrapolation algorithm of the ASPEN RoMi method calculates an extrapolated PSS D_{γi,EX}(f) per measurement signal γᵢ(t) and measurement file. When a measurement file is present for each traveled route, and T_{Ri} was indicated as the total travel time on the route i, the extrapolated PSS D_{γi,EX}(f) shows, in a frequency-dependent manner, the pseudo-damage that computationally arises at the considered point (on the component or the component mounts, and only at this point) for the total travel time T_{Ri} on the considered route. Since the travel time on a route does not cover the full required component service life T_{LD} (it is still assumed or required that the component is supposed to be designed for a complete route mix), and T_{Ri}<T_{LD}, the extrapolated PSS D_{γi,EX}(f) form a secondary result of the SPEX algorithm.

Nevertheless, the extrapolated PSS D_{γi,EX}(f) have an important practical significance. They make it possible to compare the severity of various routes of a route mix. When D_{γi,EX}(f), calculated for an identical measuring point from journeys on various routes, are placed (for example, graphically) one over the other, conclusions can be drawn regarding which route in which frequency range is more damaging than another route for the considered point. It should be noted, however, that the travel times on various routes are optionally unequal, for example, T_{R1}≠T_{R2}≠T_{R3}, etc.

### Superposition of the PSS for Route Journeys:

The superposition of the PSS in the ASPEN RoMi method is described using the formula (3.4). It is carried out after the extrapolation and is a procedure of simply adding multiple previously extrapolated PSS D_{γi,EX}(f) of the signals γᵢ(t) of an identical measurement variable γ to form an overall PSS D_{γ,SPEX}(f). The PSS are added individually for each frequency f. An implication of this is that the superposed PSS D_{γ,SPEX}(f), which applies for the entire route mix, is always more damaging at all frequencies than each of the extrapolated PSS D_{γi,EX}(f), which represent the pseudo-damage only on individual routes. This also makes sense because the total travel time on the route mix T_{RM} is greater than the travel time on each individual route T_{Ri}, see formula (3.1).

As mentioned above, the superposition algorithm of the ASPEN RoMi method calculates one superposed PSS D_{γ,SPEX}(f) per measurement variable γ. This PSS D_{γ,SPEX}(f) determines the pseudo-damage that the component will computationally sustain at the particular measuring point for the full predefined service life T_{LD} at every vibration frequency f. Thus, all superposed PSS D_{γ,SPEX}(f) form the main result of the calculations in the SPEX module. However, as an implication thereof, the superposed PSS are not formed when only one measurement file for the profile creation has been supplied to the method. This could be the case, for example, when measurements have been carried out only on one route (no route mix).

### Extrapolation of the PSS of the Reference Signal:

The PSS of the reference signal Dᵣ(f) (previously calculated in the FDDC algorithm) is extrapolated according to (3.5). The extrapolation factor kᵣ required for this purpose is determined according to (3.6). Since this formula contains the duration of the vibration test T_{VT}, this must be committed to at the latest in this level of the profile creating using the ASPEN RoMi method.

Since the reference signal is one single signal, the superposition is omitted for its extrapolated PSS.

### Typical Example Implementation:

An example is given here of the execution of the SPEX algorithm (also referred to as the extrapolation and superposition process P2) for two measurement variables x, y (γ=x, y), the signals of which have been recorded in tests on n different routes of a route mix. x, y can be, for example, the acceleration variables again, measured at two different points of the tested component, or at the component mounts. Signals of these variables x and y, measured on a section of the i^{th} route (i=1, . . . , n), are referred to as xᵢ(t), yᵢ(t) and their measurement times are referred to as tₓᵢ, t_{yi} (in general tₓᵢ≠t_{yi}). The PSS Dₓᵢ, D_{yi} were previously calculated in the FDDC algorithm, now they are fed together with tₓᵢ, t_{yi} to the SPEX module.

FIG. 6 illustrates the operating sequence of the extrapolation and of the superposition. First, the PSS Dₓᵢ, D_{yi} are extrapolated. For this purpose, the total travel time T_{Ri} on each route i is indicated (the ratio T_{Ri} to the required service life of the component T_{LD}. is still determined according to (3.1)), and the extrapolation factors kₓᵢ and k_{yi}, respectively, are calculated according to (3.3). The extrapolation of the PSS Dₓᵢ, D_{yi} is carried out by multiplying these by the corresponding extrapolation factor kₓᵢ or k_{yi}, respectively, according to the formula (3.2).

The extrapolated PSS formed in this way are referred to as D_{xi,EX}(f), D_{yi,EX}(f) in FIG. 6 (i=1, . . . , n). These are now superposed. This is carried out by adding all PSS D_{xi,EX}(f) of the channel x and all PSS D_{yi,EX}(f) of the channel y from the individual routes to one another according to (3.4). As a result, one superposed PSS is formed for each measurement variable γ, i.e., a total of two PSS D_{x,SPEX}(f), D_{x,SPEX}(f) in the considered example.

The results of the execution of the SPEX algorithm in the considered example (see FIG. 6) are, therefore:
multiple extrapolated PSS D_{xi,EX}(f), D_{yi,EX}(f) (two PSS per route i, the secondary result), and
the extrapolated and superposed PSS D_{x,SPEX}(f), D_{y,SPEX}(f) (a total of 2 PSS, the main result).

They can all be supplied to the PRGN algorithm for calculating various profiles.

### Calculation of the Test Profile (PRGN Algorithm):

The PRGN algorithm is used to determine the profile amplitudes from the PSS. The ASPEN transformation (AT) is used for this purpose.

The PRGN algorithm is first described in detail in “Description” below. Types of the resultant profiles that the PRGN algorithm (and thus the entire ASPEN RoMi method) calculates are explained in “Types of results profiles” below. Then, the AT for two separate cases—the creation of a noise profile and a sweep profile—is indicated in “ASPEN transformation” below.

### DESCRIPTION

### Input Data:

The input data of the PRGN algorithm are:
i) the extrapolated PSS D_{γi,EX}(f), or extrapolated and superposed PSS D_{γ,SPEX}(f) for route journeys (calculated in the SPEX algorithm)
ii) the extrapolated PSS D_{r,EX}(f) of the reference signal r(t) (also calculated in the SPEX algorithm)
iii) Parameters of the reference signal r(t):
   the amplitude S_{Ref}, if the reference signal r(t) was generated as a sweep (for creating a sweep profile), or
   the level of the PSD PSD_{Ref}, if the reference signal r(t) was generated as a white noise (for creating a noise profile).

### Designations:

Regardless of whether this is the extrapolated PSS or the extrapolated and superposed PSS, the profile calculation in the PRGN module is carried out according to an identical algorithm. All that matters when carrying out the PRGN calculations is the differentiation of the measurement signals γᵢ(t) when profiles are to be created from the extrapolated, non-superposed PSS D_{γi,EX}(f), or the differentiation of the measurement variables r(see the definition of the term “measurement variable,” above), when profiles are to be created from extrapolated and superposed PSS D_{γ,SPEX}(f); and this is the case only when a multi-point control has been defined. In order to clearly explain the function of the PRGN module, a case will therefore be discussed in the following, in which the PSS of the total number p of measurement signals (or measurement variables) from any SPEX result file is supposed to be evaluated using the PRGN algorithm, and q of these are intended for a multi-point control (q≤p). The input PSS of the PRGN algorithm, which have been calculated using the SPEX algorithm (see these above, in the subsection “Input data”), are renamed as compared to the above definition as follows:
D_{γi,EX}=D_{U,k}—the extrapolated PSS of the measurement signal γᵢ(t) of a measurement variable γ; measured on a travel route (the index i, which determines the number i of the route, is insignificant for the explanation of the PRGN algorithm and is therefore omitted; instead, the measurement signals, measured on this route, are simply numbered; thus the extrapolated PSS of a measurement signal is given a consecutive number k: k=1, . . . , p),
D_{γ,SPEX}=D_{U,k}—the superposed PSS for the measurement variable γ, calculated for journeys on all routes of a route mix; these superposed PSS of each measurement variable are also simply numbered with the index k in this case as well (k=1, . . . , p).

In other words, since the extrapolated, but not superposed, PSS do not need to differ from the extrapolated and superposed PSS for the explanation of the PRGN algorithm, their PSS are therefore then uniformly referred to as D_{U,k}, wherein k is the consecutive number of the measurement signal or of the measurement variable in an input file supplied to the PRGN module.

### Description of the PRGN Algorithm:

From the PSS D_{U,k} of the total number p of measurement signals (or measurement variables) of an input file (k=1, . . . , p), p individual profiles or profiles for single-point control PR_{V,k}, and a profile PR_{MP} for a multi-point control, are calculated in the PRGN module. This is carried out in the following steps:

### a) ASPEN Transformation (AT)

First, the level of an individual profile PR_{U,k} is calculated from each extrapolated, or extrapolated and superposed PSS D_{U,k}, which indicates the extrapolated PSS D_{r,EX}(f) of the reference signal, its amplitude S_{Ref} or its PSD PSD_{Ref} and the slope coefficient k_{WL} of the simple S-N curve (which is described by equation (3.8)). Depending on the type of test profile to be created, this is carried out by the AT (3.16) or (d). Specifically,
for the case of creating a sweep profile, the AT is used in the form (3.17); in (3.17), the amplitude S_{Ref} of the previously generated sweep reference signal is indicated,
for the case of creating a noise profile, the AT is used in the form (3.16); in (3.16), the level of the PSD PSD_{Ref} of the previously generated white noise reference signal is indicated.

In the AT, an identical value of the slope coefficient k_{WL} of the S-N curve must be used, as previously in the FDDC algorithm when calculating the PSS from the signals, recorded during the route journeys, and from the reference signal

### b) Profile Calculation for a Multi-Point Control

In the considered case, q measuring points from the total number p of available measuring points are provided for the multi-point control. The individual profiles PR_{U,k} of these q measuring points are then taken into account with one another to form one profile PR_{U,MP}. A distinction can be made between the strategies of average value control and maximum value control. In order to obtain a profile that is suitable for average value control, the individual profiles of all corresponding points at each frequency are arithmetically averaged:

$${PR}_{U , MP} = {q}^{- 1} \times {\sum }_{k = 1}^{q} {PR}_{U , k} \qquad ( 3.1 )$$

However, a profile that is suitable for the maximum value control is formed from the highest amplitude of all individual profiles at every frequency (“peak hold” method):

$${PR}_{U , MP} = Max \{ {PR}_{U , 1} , … , {PR}_{U , q} \} \qquad ( 3.11 )$$

c) Weighting with Safety and Test Factor

The calculated profiles PR_{U,k} and PR_{U,MP} can be used already in this form for the vibration test (with the profile control at the corresponding points). However, the result of the component test using such profiles could often not provide sufficient confidence, as is necessary for a series release. The reasons for this are as follows: these profiles neither account for the variance or distribution of the stressing and strength or stress capacity of the test specimens nor for the uncertainty of the test result due to a limited scope of random samples (i.e., the uncertainty due to testing a limited number of test specimens). Therefore, to increase the confidence in the test result, and in accordance with a corresponding approach in the context of durability, a possibility to increase the calculated profile amplitudes is provided in the ASPEN RoMi method. For this purpose, a safety and test factor j_{STF} is introduced and is applied to the previously calculated profile amplitudes as follows (jS_{TF}>1):
when creating a sweep profile, each ordinate of PR_{U,k} and PR_{U,MP} is multiplied by the factor j_{STF} (k=1, . . . , p):

$${PR}_{V , k} = {PR}_{U , k} \times {j}_{STF} \qquad ( 3.12 )$$

$${PR}_{MP} = {PR}_{U , MP} \times {j}_{STF} \qquad ( 3.13 )$$

when creating a noise profile, each ordinate of PR_{U,k} and PR_{U,MP} is multiplied by the squared of the factor j_{STF} (k=1, . . . , p):

$${PR}_{V , k} = {PR}_{U , k} \times {( {j}_{STF} )}^{2} \qquad ( 3.14 )$$

$${PR}_{MP} = {PR}_{U , MP} \times {( {j}_{STF} )}^{2} \qquad ( 3.15 )$$

The reason for the difference between the formulas (3.12) and (3.14), and between (3.13) and (3.15) is as follows. In the case of a sweep profile, PR_{U,k} and PR_{U,MP} are curves of the amplitude of a harmonic vibration with respect to frequency, as are known in a common definition of a sweep profile (for an acceleration variable, for example, these are scaled in m/s²), while, in the case of a noise profile, they are the PSD (for the acceleration, the unit is then (m/s²)²/Hz). A PSD has a physical similarity to the squared signal amplitudes.

For a practical use case, the safety and test factor j_{STF} must be established on the basis of engineering considerations and/or taken from known literature in the context of durability, for example, [15].

As the result of carrying out the steps a)-c), there are p individual profiles or profiles for a single-point control PR_{V,k} (k=1, . . . , p), and a profile PR_{MP} for a multi-point control. Similarly to the extrapolation and the superposition of the PSS (SPEX algorithm), the level of the test profiles in the PRGN algorithm is calculated individually for each frequency f, regardless of the other frequency. Therefore, the character f was omitted in all PSS D_{U,k} and profile functions PR in the above description, steps a)-c).

### Typical Exemplary Embodiment

The PRGN algorithm described above in a general manner will now be illustrated using a specific example.

Assuming that, after the route journeys and the FDDC and SPEX calculations have been carried out, extrapolated or extrapolated and superposed PSS for three measurement signals or “measurement variables” x(t), y(t), z(t) are available (in a file). These three PSS are referred to as D_{U,k} (k=1, . . . , 3). The first two variables x(t), y(t) are provided for a multi-point control. The profiles to be created must cover these PSS.

The sequence of the profile calculation using the PRGN algorithm, steps a)-c), for this case is shown in FIG. 7. Apart from the three PSS D_{U,k}, further input variables are needed for the algorithm: the extrapolated PSS D_{r,EX} and the level Aᵣ of the reference signal r(t). It is the constant amplitude S_{Ref} of the harmonic signal r(t) when sweep profiles are to be created, or the PSD of the constant amplitude PSD_{Ref} of the stochastic signal r(t) (white noise) when noise profiles are supposed to be created: Aᵣ={S_{Ref}, PSD_{Ref}}.

First, the three individual profiles PR_{U,k} are calculated (k=1, . . . , 3) from these input values, while indicating the slope coefficient k_{WL} of the S-N curve, using AT (3.16) or (3.17). The profiles PR_{U,1}, PR_{U,2} of the first two variables x(t), y(t) are then combined with one of the formulas (3.10) or (3.11) to form a profile PR_{U,MP} for a multi-point control. In FIG. 7, these formulas are expressed by the operator Φ. Depending on the type of profiles to be created (sweep or noise), the ordinates of all 4 profiles are finally multiplied by the safety and test factor j_{STF} or by the square thereof (j_{STF})².

In the considered example, the result of the PRGN calculations form the four profile functions PR_{V,k} (k=1, . . . , 3) and PR_{MP}. Depending on the handling of the reference signal and the use of the formula of the AT (3.16) or (3.17), they can all be either sweep profiles or noise profiles. The first three PR_{V,k} are individual profiles; they are determined for vibration testing using the profile control at individual points at which signals of the variables x(t), y(t), z(t) were recorded during the route journeys. The profile PR_{MP} is to be converted by the multi-point control of the signals of the two sensors, positioned as precisely as possible at the points of the recording of the variables x(t) and y(t) in the route journeys. The strategy of profile control at these two points (average value control or maximum value control) depends on whether the formula (3.10) or (3.11) was used to calculate the amplitudes of the profile PR_{MP}.

### Types of Results Profiles:

Depending on the input data and the parameterization, the PRGN algorithm (and thus the entire ASPEN RoMi method, optionally in one pass) calculates test profiles of multiple different types, or profiles having various features.

Their description follows, including information for converting the profiles of various types, if applicable:

### a) Sweep and Noise Profiles, Profiles for Dwell Time Testing

This is the differentiation of the test profiles with respect to the type of generated vibrations—with harmonic or stochastic excitation of vibrations. This first category includes testing with sweep excitation (sweep), consisting of one tone (individual sweep) or of multiple tones (multi-sweep), and the dwell time test with a fixed frequency. All these test types are standardized by DIN EN 60068-2-6. A limitation of the ASPEN method is that frequency bands of the individual sweep tones may not overlap in the case of a multi-sweep profile. The second category includes broadband noise testing according to DIN EN 60068-2-64. The ASPEN method can also be used to create profiles for combined excitation, in which one or more sweep tones are superposed with noise. This type of testing is standardized by DIN EN 60068-2-80. The prerequisite for this is that, at one frequency, only one profile amplitude (for example, only the amplitude of the sweep profile or only the value of the PSD of the noise profile) must be determined.

### b) Excitation and Response Profiles

It makes sense to carry out the measurement of the vibration variables, load variables, or stress variables for the profile creation using the ASPEN method both on the component in question and on the mounting or connection points of the component on the carrier (a carrier can be, for example, an internal-combustion-engine drive or an electrical propulsion system, or another type of drive, of a motor vehicle, a motor vehicle transmission, a body, or a vehicle axle).

Excitation profiles are derived from data that have been measured at holding or mounting points of the component in question using the ASPEN method. They are used to generate vibrations that are introduced into this component (the test specimen) during the vibration test. In most cases, the excitation profile is also controlled in a closed loop.

When vibrations are also recorded directly on the component in question (during the route journeys), response profiles can be calculated from these data using the ASPEN method. They describe desired or required vibration amplitudes that the test specimen is intended to undergo during the vibration test as a response to the introduced excitation profile. In contrast to an excitation profile, the response profile of resonant components is only rarely used for a shaker control, for various reasons.

The excitation and response profiles are differentiated only by the selection of the measuring points for which a profile is derived, and their handling during the vibration test—closed-loop control of an excitation profile, or monitoring (optionally with limitation) on the basis of the response profile. In the ASPEN method, the excitation and response profiles are created according to an identical algorithm.

### c) Profiles for Single-Point Control and Multi-Point Control

The difference between these profile types is whether a profile is controlled in a closed loop at one point or at multiple points in a vibration test. In single-point control, a vibration sensor is placed at one point on the test rig and the vibrations are introduced into the structure at this point according to a specified profile. In multi-point control, the specified profile is controlled according to signals of multiple vibration sensors that have been positioned at various points on the test rig.

Profiles for the single-point control are created by default in the ASPEN RoMi method PRGN module, from all signals measured on a route or on the complete route mix, using the above-described procedure. When signals have been recorded at multiple points on the component or on the component mounts in different directions (during the driving tests), the only difference between these profiles is the point and the measurement direction for which they apply. Therefore, when a test profile PR_{V,k} has been created using the PRGN algorithm from the signal of a sensor having the consecutive number k, the profile can be meaningfully used only in the test with the profile control at the corresponding point at which this sensor was positioned in the route journeys, and in the corresponding direction (measurement direction of the sensor).

Profiles for multi-point control can be created from all signals measured on a route or on the complete route mix, in their arbitrary combination. These signals only need to be specified. If the extrapolated or the extrapolated and superposed PSS D_{U,k} for p measurement signals are present in an SPEX results file, q arbitrary signals thereof can be indicated in the PRGN module for calculating a profile PR_{MP} for multi-point control (2≤q≤p). Such a test profile PR_{MP}, created by joint processing of the q individual profiles according to the formulas (3.10), (3.11), should also be controlled in a closed loop in the vibration test according to the signals of all these q sensors, positioned at the corresponding points. This means, this profile can be correctly implemented only by the multi-point control of the signals of the corresponding sensor sites. The control strategy should also correspond to the algorithm for calculating the individual profiles. If the formula (3.10) was used for this purpose, an average value control should be applied. If the formula (3.11) was used, a maximum value control should be applied. These control strategies are to be implemented in the vibration control system of the test rig by corresponding settings.

A test profile for multi-point control is not calculated when only one measurement file (see above) was supplied to the ASPEN RoMi method for the profile creation. This could be the case, for example, when measurements have been carried out only on one route (no route mix).

d) Profiles that Cover the Damage on Individual Routes or on the Entire Route Mix

If measurements are carried out on multiple different design-relevant routes of a route mix, profiles are created in the ASPEN RoMi method that cover the damage both on each individual route and on the entire route mix. This is carried out in one pass of the method.

### Individual Routes

The profiles PR_{V,k}, PR_{MP}, created from the extrapolated, but not superposed, PSS, cover the travel time T_{Ri} only on a route i under consideration. They neither account for journeys on other routes of the route mix nor do they cover the full required component service life T_{LD} (it is still assumed or required that the component is to be designed for a complete route mix). In addition, since T_{Ri}<T_{LD}, such a profile is weaker than the profile that covers the complete route mix and thus the required component service life. Profiles that cover the travel time T_{Ri} only on individual routes of a route mix may therefore have secondary significance for a practical vibration test. With this in mind, these profiles form only a secondary result of the profile creation by the ASPEN RoMi method.
Nevertheless, the profiles PR_{V,k}, PR_{MP}, created from the extrapolated, non-superposed PSS, have important practical significance. Reference has already been made above (see last paragraph in the subsection “Extrapolation of the PSS for route journeys”) to the possibility (and necessity) of using these PSS for a comparison of the severity of various routes of a route mix. This problem can then be solved in another way by the profiles created from these PSS. When PR_{V,k} or PR_{MP}, calculated for an identical measuring point or for the identical measuring points from journeys on different routes, are placed one over the other (for example, graphically), conclusions can be drawn regarding which route in which frequency range for the point(s) in question leads to a more severe profile in a vibration test than that of another route. A more severe profile means greater (pseudo) damage. It should be noted again, however, that the travel times on various routes are optionally unequal: T_{R1}≠T_{R2}≠T_{R3} etc.

### Route Mix

Only the profiles PR_{V,k}, PR_{MP}, created from the extrapolated and superposed PSS, cover the travel time on the entire route mix and thus the full specified service life T_{LD} of the component. These therefore form the main result of the profile creation of the ASPEN RoMi method. In each profile, this result is accurate, however, only in the case of profile control at a corresponding, specific point (for an individual profile PR_{V,k}), or at the multiple corresponding points (for the profile PR_{MP}). These are various points (on the component or on the component mounts), the signals of which were used to create the profiles PR_{V,k}, PR_{MP}.

The profiles are assigned to the groups a)-d) on the basis of the input data and the establishment of the calculation parameters.

The features from the groups a)-d) are not contradictory. Each created profile contains one feature from each group. For example, a test profile can be a sweep profile with respect to the type of generated vibrations, an excitation profile with respect to the selection of the points for the control/application thereof, a profile for multi-point control with respect to the number of control points, and simultaneously cover the travel time on only one route or on the entire route mix. All these profiles are usable. It is up to the technician to select one of these profiles for the practical implementation of the vibration test.

### Aspen Transformation:

Here, formulas are indicated for converting the PSS, calculated using the ASPEN method from the route journeys (i.e., pseudo-damage that the component sustains during the driving operation), into the damage-equivalent profile amplitudes. Simple, non-iterative, analytical formulas (3.16) and (3.17) were developed in the ASPEN method for this purpose. They were referred to as ASPEN transformation (AT) and are implemented in the PRGN algorithm (see above).

In both variants, the AT applies only for a simple S-N curve. This is described by the equation (3.8). As taken from the formulas (3.16), (3.17), the sought profile level in this case is dependent only on the slope coefficient k_{WL}, and not on the abscissa or ordinates of the support point of the S-N curve.

Which of the formulas is used depends only on the type of profile to be created. A distinction is made between two profile types:

### a) Noise Profiles

A profile of this type requires a stochastic excitation of vibrations; it is described by a PSD. The AT for the calculation of the level of the PSD of a noise profile at a frequency f is:

$${PSD}_{U} ( f ) = {PSD}_{Ref} ( f ) \times {[ \frac{{D}_{U} ( f )}{{D}_{Ref} ( f )} ]}^{( \frac{2}{{k}_{WL}} )} \qquad ( 3.16 )$$

wherein PSD_{U}(f)—the sought level of the PSD of the noise profile,
   PSD_{Ref}(f)—the level of the PSD of the stochastic reference signal,
   D_{U}(f)—the ordinate of the PSS, which arises for stochastic vibration with the sought PSD PSD_{U},
   D_{Ref}(f)—the ordinate of the PSS of the reference signal with the PSD PSD_{Ref}(f),
   k_{WL}—slope coefficient of the S-N curve.

The AT (3.16) determines the level of the PSD PSD_{U} of a stochastic vibration at a frequency f in order to obtain the defined (required) damage value D_{U} at this frequency. A known correlation is used to calculate the PSD PSD_{U} from D_{U}, according to which another stochastic vibration (referred to as the reference signal) generates the damage value D_{Ref} using the PSD PSD_{Ref} at the identical frequency. This correlation is obtained using a procedure that includes generating a reference signal (here: a stochastic vibration signal) suitable for the profile type using the known PSD PSD_{Ref} and calculating the damage value D_{Ref} thereof at each frequency; see the right part of the diagram in FIG. 4. This procedure is described in detail above.

The calculation PSD_{U}(f) in (3.16) is carried out for each vibration frequency f individually, regardless of another frequency.

In the formula names in the section in which the PRGN algorithm is described (see the section with the heading “Description,” above), the following applies: D_{U}(f)=D_{U,k}(f), PSD_{U}(f)=PR_{U,k}(f) (the index k is omitted, since (3.16) relates to an arbitrary signal), D_{Ref}(f)=D_{r,EX}(f).

The formula (3.16) is proven mathematically further below. This is based on the consideration of the relationship between the PSD and the PSS of an ergodic, normally-distributed noise signal and the scaled copy thereof.

### b) Sweep Profiles

A profile of this type requires a harmonic excitation of vibrations; it is described by the dependence of the amplitude S of such a harmonic vibration signal on the instantaneous frequency f, thereof, i.e., as an AFV S(f).

The AT for calculating the AFV of a sweep profile (consisting of a single sweep) at a frequency f is:

$${S}_{U} ( f ) = {S}_{Ref} ( f ) \times {[ \frac{{D}_{U} ( f )}{{D}_{Ref} ( f )} ]}^{( \frac{1}{{k}_{WL}} )} \qquad ( 3.17 )$$

wherein S_{U}(f)—the sought amplitude of the AFV of the sweep profile,
   S_{Ref}(f)—the amplitude of the AFV of the monoharmonic reference signal,
   D_{U}(f)—the ordinate of the PSS that arises for monoharmonic vibration having the sought amplitude S_{U},
   D_{Ref}(f)—the ordinate of the PSS of the reference signal with the AFV S_{Ref}(f),
   k_{WL}—slope coefficient of the S-N curve.

The AT (3.17) determines the amplitude S_{U} of a monoharmonic vibration at a frequency f in order to obtain the defined (required) damage value D_{U} at this frequency. A known correlation is used to calculate the AFV S_{U} from D_{U}, according to which another monoharmonic vibration (referred to as the reference signal) having the amplitude S_{Ref} generates the damage value D_{Ref} at the identical frequency. This correlation is obtained using a procedure that includes generating a reference signal (here: an individual sweep signal) suitable for the profile type using the known amplitude S_{Ref} and calculating the damage value D_{Ref} thereof at each frequency; see the right part of the diagrams in FIG. 1 and FIG. 4. This is described in detail further below.

The calculation S_{U}(f) in (3.17) is carried out for each vibration frequency f individually, regardless of another frequency.

In the formula names in the section in which the PRGN algorithm is described (see the section with the heading “Description,” above), the following applies: D_{U}(f)=D_{U,k}(f), S_{U}(f)=PR_{U,k}(f) (the index k is omitted, since (3.17) relates to an arbitrary signal), D_{Ref}(f)=D_{r,EX}(f).

Apart from the individual sweep profiles, the AT (3.17) can also be applied to creating the following profiles:
i) profiles for dwell time testing with monoharmonic excitation at a fixed frequency (fixed frequency sinusoidal curve); these can be considered to be a special case of the individual sweep profiles when the sweep frequency remains constant, and
ii) profiles with multi-sweep excitation.

In the case ii), the limitation of the ASPEN method is that frequency bands of the individual sweep tones of a multi-sweep profile may not overlap. Due to this limitation, only one individual sweep profile is ever defined at each frequency also in the case of a multi-sweep profile. The formula (3.17) is therefore also valid for this case.

The formula (3.17) is proven mathematically further below. This is based on the observation of the relationship between the amplitudes and the PSS of a monoharmonic time signal having a fixed frequency and its scaled copy.

### Concept of the Reference Signal:

As mentioned above, all damage-based profile creation methods have the problem of converting the damage figures, which the component sustains during the driving operation, into the damage-equivalent amplitudes of the test profile. The difficulty is that the relationship between these two variables must be known in order to carry out such a conversion in a non-recursive manner. This problem is solved in the ASPEN method on the basis of the concept of the reference signal and the AT. The AT, described by the formulas (3.16) and (3.17), was discussed in the section “ASPEN transformation.” The concept of the reference signal is discussed here.

In principle, this is based on the fact that, depending on the profile type, a specifically defined time signal is automatically generated, the PSS thereof is calculated and is extrapolated for the established duration of the vibration test; see the right part of the diagram in FIG. 4 (this signal can be generated method-internally or method-externally). Since the amplitude (or the PSD) of this signal was established in advance, and the PSS thereof is calculated, this procedure solves the above-described problem. The relationship between these two characteristic variables, which is needed to convert a PSS into the damage-equivalent profile amplitudes, is therefore known at every frequency. A signal generated this way is referred to in the ASPEN method as the reference signal. The type thereof absolutely must correspond to the type of the test profile to be created. For example, it must be generated as a sweep when calculating a sweep profile, or as a stochastic signal when a noise profile is calculated.

Specifically, the concept of the reference signal for creating a test profile in the ASPEN RoMi method calls for carrying out the following steps:

### a) Establishing the Profile Type and Profile Parameters

At the latest at this point in time of creating the profile, the type of test profile to be created and the duration of the vibration test T_{VT} must be established (note: the test frequency range fᵤₙₜ, . . . , f_{ob} must have been selected earlier, for the FDDC evaluation of the signals measured during the route journeys; see above.)

The types of the profiles that can be created using the ASPEN method are:
sweep profiles (individual or multi-sweep)
profiles for a dwell time test (sinusoidal excitation with a fixed frequency), and
noise profiles (test with stochastic vibration excitation).

### b) Generating the Reference Signal

Depending on the profile type and profile parameters selected above, a reference signal is then generated; specifically:

### Sweep Profiles

For individual sweep profiles—the reference signal is generated in the entire test frequency range fᵤₙₜ, . . . , f_{ob} as an individual sweep of the selected type (linear, logarithmic), with the amplitude S_{Ref}, sweep rate R, and duration tᵣ. The duration tᵣ must include a whole number of the half sweep cycles (this is the sweep time from the lower frequency to the upper frequency of a sweep sinusoidal signal). The amplitude S_{Ref} may be arbitrarily selected, although it must be constant in the entire frequency range fᵤₙₜ, . . . , f_{ob}.
For multi-sweep profiles—the reference signal consists, in this case, of n_{Swp} individual sweep tones (n_{Swp}=2; 3; 4; . . . ); each of these is defined in a separate frequency band, with the following partitioning [f_{Swp,1}; f_{Swp,2}], . . . , [f_{Swp,l-1}; f_{Swp,l}], l=n_{Swp}+1 (f_{Swp,1}=fᵤₙₜ, f_{swp,l}=f_{ob}); together, they cover the entire test frequency range fᵤₙₜ, . . . , f_{ob}. The individual frequency bands must not overlap. The type (linear, logarithmic), the amplitude S_{Ref}, and the sweep rate R must be selected as the same for each sweep tone (and the sweep rate R ensures this condition that all individual sweeps have an identical run time of their own frequency band, i.e., these run synchronously). In this case as well, the duration tᵣ must be a whole number of the half sweep cycles, and the amplitude S_{Ref} must be constant in the entire frequency range fᵤₙₜ, . . . f_{ob}.

### Profiles for Dwell Time Testing

This is the simplest case. The reference signal is generated here as a monoharmonic vibration of the selected duration tᵣ (preferably at least 1000 periods of the sinusoidal vibration) with a fixed frequency f_{Ref}; this is the test frequency. The amplitude S_{Ref} of the vibration can be arbitrarily selected, as is the case for the sweep profiles.

### Noise Profiles

The reference signal is generated here as a stationary stochastic signal having a power density PSD_{Ref} that is constant across the entire test frequency range, i.e., as a white noise. The value of the PSD PSD_{Ref} may be arbitrarily selected. With respect to the duration tᵣ of this vibration, it should be as great as possible in order to reduce the deviation between the actual PSD of the reference signal and the specified value PSD_{Ref}. In practical applications, the signal duration tᵣ=400 s has proven to be sufficiently long.
When a noise signal of this type is generated by PC-supported signal processing software (for example, Matlab, Famos, Labview, etc.), the functions contained therein for generating random numbers can be used for this purpose (for example, this function is called “Random” in Famos. It yields a digital white noise signal in the frequency band up to the Nyquist frequency).

### c) Calculating the PSS

Once the reference signal r(t) has been generated in the above-described manner, its PSS Dᵣ(f) is calculated. For this purpose, the FDDC algorithm is carried out once more; see the computing block 13 in the right part of the diagram in FIG. 4. The same calculation parameters must be used as for the calculation of the PSS of the signals from the route mix journeys (see above). In particular, this applies to the configuration of the band pass filters, and to the classification parameters and the S-N curve parameters.

### d) Extrapolating the PSS

The PSS Dᵣ(f) calculated in the preceding point applies for the duration tᵣ of the generated reference signal. In order to calculate a damage-equivalent profile using the ASPEN method, however, the damage figures are required, which damage figures would (computationally) arise in the entire vibration test having the duration T_{VT}. The PSS Dᵣ(f) is extrapolated to this duration T_{VT} for this purpose. This is carried out by running the SPEX algorithm once more; see the computing block 14 in the right part of the diagram in FIG. 4. The extrapolation algorithm is described therein by the formula (3.5). The extrapolation factor kᵣ required therefor is determined according to (3.6).

The extrapolated PSS D_{r,EX}(f), which applies (computationally) for the established duration T_{VT} of the vibration test, forms the result of all calculations for the reference signal. This PSS is used further in the PRGN algorithm to determine the profile amplitudes (see the section “Description,” subsection “Description of the PRGN algorithm,” point a)).

### Practical Tips:

In principle, the following possibilities for generating the reference signal are available:
Generating this as a real vibration signal on a vibration test rig equipped with a suitable control system. Since the reference signal is only necessary for calculating a relationship between its amplitudes (or the PSD) and the degree of damage for the profile of a certain type, the test specimen does not need to be set up for this purpose. The necessary vibration signal can be recorded on an empty shaker plate, i.e., without a test specimen. This applies regardless of whether the current test profile calculation is an excitation profile or a response profile.
Generated as a fictitious, digital signal in a PC-supported signal processing tool (for example, in Matlab, Famos, Labview, etc.). This is an alternative, time-saving and affordable possibility, since it requires neither a vibration test rig for generating vibrations nor a measuring system for recording the signals. Formally speaking, the amplitudes of a reference signal generated in this way can have any unit or even no unit at all, since the signal is fictitious. In order to work correctly with the ASPEN method, however, a unit that is identical to the unit of the ordinates of the signals from the route journeys for which test profiles are intended to be created absolutely must be assigned to the ordinates of the generated reference signal. The unit for the amplitude S_{Ref} and for the PSD PSD_{Ref} of the digital reference signal to be created must also be correspondingly selected, specifically:
   The unit of the amplitude S_{Ref} for generating the reference signal of the sweep type (when an individual sweep profile or a multi-sweep profile is created) or of the type of a harmonic vibration with a fixed frequency (when creating a profile for a dwell time test) must be identical to the unit of the signals from the route journeys for which test profiles are to be created (for example, the unit S_{Ref} for the variable acceleration—m/s²).
   The unit of the PSD PSD_{Ref} for generating the white noise reference signal must be identical to the unit of the noise profiles to be created (for example, the unit PSD_{Ref} for the variable acceleration, which was measured in m/s²—(m/s²)²/Hz).

### Further Tips:

It must be ensured that the signal parameters used to generate the reference signal (for example, the sweep rate, the number of individual sweep tones, and the frequency bands thereof) are identical to those that are actually used in the subsequent conversion of the created test profile on a vibration test rig for the vibration test of the test specimen.
The same reference signal, which has been generated once, can be used to create an excitation profile and a response profile which relate to a test specimen and are used together in the vibration test of the test specimen.

### Further Explanations/Attachments

Extrapolation and superposition of the PSS with multiple measurement files per travel route:

A special case for the extrapolation and superposition of the PSS in the ASPEN RoMi method is discussed here when there are multiple measurement files for each route traveled. This can be the case, for example, when storing the entire section on this route to be measured in one file would result in an excessively large amount of data. Therefore, the measuring engineer can reach a decision to repeatedly initiate and stop the measurement during the route journey. For further comments in this subsection, it is assumed that the data of each measurement interval are stored in a separate measurement file.

The allocation of the measured data into multiple measurement files can even be carried out retroactively, for example, to reduce the size of a measurement file. Since the travel time to which the PSS of the time signals of this file are extrapolated is individually specified for each measurement file in the SPEX module, it may not be indicated as the total travel time T_{Ri} on the measured route, of course, for a file of this type. Rather, the total travel time T_{Ri} must be divided between multiple sections of the route. As mentioned in the preceding paragraph, it is assumed that there is one measurement file for each route section. The sum of the travel times on all subsections should naturally yield the total travel time on the route T_{Ri}.

This description will be illustrated using a numerical example, which follows. It is assumed that an acceleration variable γ(t) was measured on two sections of a travel route i having the duration 1000 s and 1500 s and stored in 2 separate measurement files. The signals of the two sections are γ_{i,1}(t) and γe_{i,2}(t), and the corresponding measuring times are t_{γi,1} and t_{γi,2}. Thus, they are t_{γi,1}=1000 s, t_{γi,2}=1500 s; the total travel time on the route i under consideration in the context of a route mix for covering the entire service life is assumed to be, for example, T_{Ri}=5000 h.

The work with the FDDC and SPEX modules of the ASPEN RoMi method is carried out as described in the following. Initially, the two measurement files are supplied to the FDDC module and the 2 PSS D_{γi,1}(f) and D_{γi,2}(f) are calculated from the two signals γ_{i,1}(t) and γ_{i,2}(t). These PSS are also stored in individual files. They are then supplied to the SPEX module for extrapolation. Since the two PSS D_{γi,1}(f) and D_{γi,2}(f) are located in two separate files again, they are extrapolated separately, and the extrapolation algorithm requires that the 2 different travel times T_{Ri,1}, T_{Ri,2} be indicated. These are the durations of the journeys on the section of the route i, on which each measurement signal γ_{i,1}(t) and γ_{i,2}(t) was recorded. Their relationship to one another may be arbitrarily selected; it should only be ensured that their sum is the total travel time on the route: T_{Ri}=T_{Ri,1}+T_{Ri,2}. A reasonable selection of T_{Ri,1}, T_{Ri,2} would probably be that these are in an identical relationship, similar to the measurement times: T_{Ri,1}/T_{Ri,2}=t_{γi,1}/t_{γi,2}. Given such a selection, the following apply: T_{Ri,1}=2000 h, T_{Ri,2}=3000 h, and T_{Ri}=T_{Ri,1}+T_{Ri,2}=5000 h.

In that respect, the PSS D_{γi,1} is extrapolated to D_{γi,1,EX} and D_{γi,2} is extrapolated to D_{γi,2,EX} in the SPEX module. The extrapolated PSS D_{γi,1,EX} applies for the travel time T_{Ri,1} (on the first section of the route i), the extrapolated PSS D_{γi,2,EX} applies for the travel time T_{Ri,2}. The PSS D_{γi,EX}, which applies for the full travel time T_{Ri}=5000 h on the entire route i, is first calculated in the SPEX module via the superposition: D_{γi,EX}.=D_{γi,1,EX}+D_{γi,2,EX}. The main result of the SPEX calculations for the example case under consideration is obtained.

### Proof of the ASPEN Transformation:

The mathematical proof of the AT (see formulas (3.16) and (3.17)) is based on the derivation of the correlation between the amplitudes (or PSD) and the PSS, calculated for two scaled copies of an arbitrary time signal by using a simple S-N curve described by the equation (3.8). This correlation is first set up. The proof of the formulas (3.16) and (3.17) follows.

### Relationship Between the PSS of the Two Scaled Signals:

An arbitrary time signal a(t) is considered. The PSS of this signal, determined using the FDDC algorithm of the ASPEN method for a simple S-N curve (see above), is denoted by Dₐ(f). Multiplying the signal amplitudes by a fixed factor (the constant) p results in a new signal b(t)=a(t)·p. If an identical S-N curve is used to calculate the PSS D(f) of the signal b(t) using the FDDC algorithm, the PSS of the two signals a(t) and b(t) are related to one another as follows

$${D}_{b} ( f ) = {D}_{a} ( f ) \times {p}^{{k}_{WL}} \qquad ( 4.1 )$$

wherein k_{WL}—the slope coefficient of the S-N curve.

### Proof of the Equation (4.1):

It is assumed that the signal a(t) has been classified using a counting method. As a result, for each load horizon (i.e., for an amplitude) aᵢ, there is an associated number of stress cycles N_{OP}(aᵢ). aᵢ can also be the SMA when the counting method that is used determines not only the amplitude but also the average value of each cycle (for example, the rainflow counting method). The values [aᵢ; N_{OP}(aᵢ)] form a load spectrum. In FIG. 8, this is shown with a solid-lined, continuous curve. The amount of damage of each amplitude aᵢ is calculated according to (3.7)

$$D ( {a}_{i} ) = \frac{{N}_{OP} ( {a}_{i} )}{N ( {a}_{i} )}$$

wherein N(aᵢ)—the number of cycles to failure for the amplitude aᵢ (so that [aᵢ; N(aᵢ)] is a point on the S-N curve; see FIG. 8).

The overall damage figure for all amplitudes of the load spectrum that has, for example, n amplitude levels (i=1, . . . , n), is then obtained according to (3.9) as:

$${D}_{GS} ( a ) = {\sum }_{i = 1}^{n} D ( {a}_{i} ) = {\sum }_{i = 1}^{n} \frac{{N}_{OP} ( {a}_{i} )}{N ( {a}_{i} )} \qquad ( i )$$

A following relationship can be created in the same way for the overall damage figure of the signal b(t):

$${D}_{GS} ( b ) = {\sum }_{i = 1}^{n} D ( {b}_{i} ) = {\sum }_{i = 1}^{n} \frac{{N}_{OP} ( {b}_{i} )}{N ( {b}_{i} )} \qquad ( ii )$$

The load spectrum for the signal b(t) is shown schematically in FIG. 8 as a light, dashed-lined curve.

Considering an arbitrary number of cycles N_{OP}(aᵢ) of the load spectrum for aᵢ, it is simultaneously the number of cycles N_{OP}(bᵢ) of the spectrum for bᵢ with the relationship bᵢ=aᵢ·p, which arises due to the signal scaling b(t)=a(t)·p: N_{OP}(bᵢ)=N_{OP}(aᵢ) for bᵢ=aᵢ·p.

In addition, the points [bᵢ; N(bᵢ)] and [aᵢ; N(aᵢ)] lie on an S-N curve; see FIG. 8. Therefore, the equation (3.8) applies for the aforementioned points:

$${( \frac{{b}_{i}}{{a}_{i}} )}^{{k}_{WL}} = \frac{N ( {a}_{i} )}{N ( {b}_{i} )}$$

Since bᵢ/aᵢ=p, this equation can be transformed as follows

$$N ( {b}_{i} ) = \frac{N ( {a}_{i} )}{{p}^{{k}_{WL}}} \qquad ( iii )$$

After substituting in (ii) instead of N(bᵢ) of the expression (iii) and taking into account N_{OP}(bᵢ)=N_{OP}(aᵢ), the following results for D_{GS}(b)

$${D}_{GS} ( b ) = {p}^{{k}_{WL}} \times {\sum }_{i = 1}^{n} \frac{{N}_{OP} ( {a}_{i} )}{N ( {a}_{i} )}$$

or, considering (i)

$${D}_{GS} ( b ) = {D}_{GS} ( a ) \times {p}^{{k}_{WL}} \qquad ( iv )$$

Finally, a(t) can be considered to be an output signal of a narrow band pass of the type defined in the FDDC algorithm of the ASPEN method. Then D_{GS}(b), D_{GS}(a) in (iv) are the ordinates of the PSS of the signals a(t) and b(t) at a frequency, and the relationship (iv) also applies for the PSS.

The equation (4.1) is therefore proven.

### Derivation of the AT for the Case of a Noise Profile:

The mathematical derivation of the formula (3.16) is based on the following consideration. It is assumed that the reference signal a(t) is an ergodic, normally-distributed noise having the PSD PSDₐ(f) and the PSS Dₐ(f). This PSS has been determined using the above-described FDDC algorithm. From a(t), a new (reference) signal b(t) is then formed by multiplying the amplitudes a(t) by a constant p:b(t)=a(t)·p. The PSD PSD(f) of the noise signal b(t), for which its PSS is D_{b}(f) (specified value), is sought.

The PSD of the ergodic signal a(t) having the duration T can be calculated as follows using the square of its Fourier transform FTₐ(f) [14]:

$${PSD}_{a} ( f ) = ( \frac{1}{T} ) {\vert {FT}_{a} ( f ) \vert}^{2}$$

Since b(t) has been obtained by a linear transformation from the ergodic, normally-distributed signal a(t), it is also ergodic and normally-distributed [14]. The following therefore also applies for b(t)

$${PSD}_{b} ( f ) = ( \frac{1}{T} ) {\vert {FT}_{b} ( f ) \vert}^{2}$$

b(t)=a(t)·p yields, due to the linearity of the Fourier transform: FT_{b}(f)=p·FTₐ(f). Therefore, PSD_{b}(f)=p²·(1/T)|FTₐ(f)|², or

$${PSD}_{b} ( f ) = {p}^{2} \times ( \frac{1}{T} ) {\vert {FT}_{a} ( f ) \vert}^{2} \qquad ( i )$$

In addition, the relationship (4.1) (see above) applies for the PSS of the two signals a(t) and b(t):

$${D}_{b} ( f ) = {D}_{a} ( f ) \times {p}^{{k}_{WL}} \qquad ( ii )$$

(ii) yields, for the constant p

$${p}^{2} = {[ \frac{{D}_{b} ( f )}{{D}_{a} ( f )} ]}^{( \frac{2}{{k}_{WL}} )} \qquad ( iii )$$

Substituting the expression for p² from (iii) in (i) then leads to the following result

$${PSD}_{b} ( f ) = {{PSD}_{a} ( f ) [ \frac{{D}_{b} ( f )}{{D}_{a} ( f )} ]}^{( \frac{2}{{k}_{WL}} )}$$

Considering other relationships, this expression is identical to the formula (3.16).

### Deriving the AT for the Case of a Sweep Profile:

Due to the condition of the ASPEN method, mentioned above, it is sufficient to derive the formula (3.17) only for the case of an individual sweep profile. A profile of this type determines a sweep frequency sinusoidal vibration consisting of one tone. In addition, for each time interval selected to be sufficiently small, it can be assumed to be a monoharmonic vibration having a fixed frequency. This yields a further simplification, specifically that the AT (3.17) must be proven only for the case of a monoharmonic vibration having a fixed frequency.

Such a monoharmonic (reference) signal a(t) having a fixed frequency f is now considered (the frequency f can be arbitrary). The AFV of a(t) is Sₐ(f), the PSS is referred to as Dₐ(f). This PSS has been determined using the above-described FDDC algorithm. From a(t), a new (reference) signal b(t) is then formed by multiplying the amplitudes a(t) by a constant p:b(t)=a(t)·p. The AFV S_{b}(f) of the signal b(t), for which its PSS is D_{b}(f) (specified value), is sought.

Since S_{b}(f) and Sₐ(f) are the amplitudes of the two signals b(t) and a(t), it is obvious that b(t)=a(t)·p yields

$${S}_{b} ( f ) = p \times {S}_{a} ( f ) \qquad ( i )$$

In addition, the relationship (4.1) (see above) applies for the PSS of the two signals a(t) and b(t):

$${D}_{b} ( f ) = {D}_{a} ( f ) \times {p}^{{k}_{WL}} \qquad ( ii )$$

(ii) yields, for the constant p

$$p = {[ \frac{{D}_{b} ( f )}{{D}_{a} ( f )} ]}^{( \frac{1}{{k}_{WL}} )} \qquad ( iii )$$

Substituting the expression for p from (iii) in (i) then leads to the following result

$${S}_{b} ( f ) = {{S}_{a} ( f ) [ \frac{{D}_{b} ( f )}{{D}_{a} ( f )} ]}^{( \frac{1}{{k}_{WL}} )} \qquad ( iv )$$

When a(t) in (iv) is a reference signal for a sweep test, and considering other relationships, (iv) is identical to the formula (3.17).

The invention is not limited to the described exemplary embodiments. The scope of protection is defined by the claims.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### REFERENCES

1. Köhler, M.; Jenne, S.; Pötter, K.; Zenner, H.: Zahlverfahren und Lastannahme in der Betriebsfestigkeit (Load Assumption for Fatigue Design of Structures and Components). Springer, 205 pages, 2012
2. MBN 10438-2 “Dauerfestigkeit von schwingenden Motoranbauteilen—Absicherung für die Serie. Anforderungen und Vorgehensweise” (“Fatigue Strength of Vibrating Engine Components—Validation for Series Production”). Mercedes-Benz Werknorm, Version 2014 January, 22 pages
3. VW80200-1 “Motoranbauteile” (“Engine Components”). Volkswagen AG Konzernnorm, Version 2009 March, 29 pages
4. DIN 30787-5 “Messen und Auswerten von mechanisch-dynamischen Belastungen. Part 5: Ableitung von Prüfvorschriften” (“Measurement and evaluation of mechanical-dynamic loads. Part 5: Derivation of test specifications”). September 2002, 20 pages
5. Cornelis, B.; Dendas, B.; Carrella, A.: “Qualification testing of racecar equipment subject to engine-induced vibrations: how to derive a test profile using a mission synthesis procedure”, Siemens Industry Leuven. In: IMAC XXXV, Garden Grove, USA, 30 Jan.-2 Feb. 2017 (URL: https://www.researchgate.net/publication/313368832_A_Mission_Synthesis_proc edure_for_Sine-on-Random_excitations_in_a_helicopter_application)
6. Halfpenny, A.: “Accelerated Vibration Testing Based on Fatigue Damage Spectra”. nCode International, 2009 (nCode publication, URL: https://www.ncode.com/images/GlyphWorks/Downloads/Whitepaper_nCode_AH P_AcceleratedVibrationTestingBasedonFatigueDamageSpectra_v2-Halfpenny.pdf)
7. Halfpenny, A.; Kihm, F.: “Mission Profiling and Test Synthesis Based on Fatigue Damage Spectra”. 9th Int. Fatigue Congress, Atlanta, USA, 2006
8. Decker, M.; Kinscherf, S.; Hesse, R.; Dillinger, S.: “FatiResponse—Schädigungsaquivalenz in der Vibrationsprüfung” (“FatiResponse—Damage equivalence in vibration testing”). DVM-Workshop “Prüfmethodik für Betriebsfestigkeitsversuche in der Fahrzeugindustrie” (“Test methodology for fatigue strength tests in the automotive industry”), Ottobrunn, 25.-26 Jan. 2017
9. Decker, M.: “Ableitung schädigungsaquivalenter Leistungsdichtespektren für die Vibrationsprofung unter Verwendung von Schädigungs-Antwort-Spektren” (“Derivation of damage-equivalent power density spectra for vibration testing using damage response spectra”). Thesis, issue 119, TU Darmstadt, Institut für Stahlbau und Werkstoffmechanik (Institute of Steel Construction and Materials Mechanics), 133 pages, 2018
10. Patent WO 98/14765 A “Method to Specify Random Vibration Tests for Product Durability Validation”. Ford Motor Company, 1998
11. Patent U.S. Ser. No. 00/556,5618A “Method to Specify Sinusoidal Vibration Tests for Product Durability Validation”. Ford Motor Company, 1996
12. Patent EP 3433593 B1 “Method and System for Accelerated Fatigue Damage Testing of an Object”. Siemens Industry Leuven, 2016
13. Patent DE 10236735 A1 “Verfahren zur Generierung von zum Fahrbetrieb schädigungsäquivalenten Rauschprofilen zur Vibrationsprüfung von Fahrzeugkomponenten” (“Method for generating noise profiles equivalent to driving damage for vibration testing of vehicle components”). BMW AG Muinchen, 2002
14. Bendat, J; Piersol, A.: Random Data. Analysis and Measurements Procedures. John Wiley, 566 pages, 1986
15. Haibach, E.: Betriebsfestigkeit. Verfahren und Daten zur Bauteilberechnung (Fatigue strength. Methods and data for component calculation). Springer, Version 2, 2002, 753 pages

### REFERENCE CHARACTERS

1.1, 1.2, . . . , 1.n measurement signals
2.1, 2.2, . . . , 2.n pseudo-damage spectra
3 superposed pseudo-damage spectrum
4 test profile (route mix)
5 reference signal
6 extrapolated reference signal pseudo-damage spectrum
7.1, 7.2, . . . , 7.n extrapolated pseudo-damage spectra
8.1, 8.2, . . . , 8.n test profiles (individual routes)
9.1, 9.2, . . . , 9.n measurement files
10 pseudo-damage calculation parameter
11 extrapolation and superposition calculation parameter
12 test profile calculation parameter
13 pseudo-damage spectrum calculation component
14 extrapolation subcomponent
15 superposition subcomponent
16 test profile generation component
17 reference signal pseudo-damage spectrum
18 reference signal extrapolation parameter
   For the special embodiment of the method in FIG. 9:
m—number of travel routes
n—number of measurement variables recorded on each route
MS_{i,j} i=1, . . . , m, j=1, . . . , n—measurement signal
PS_{i,j} i=1, . . . , m, j=1, . . . , n—pseudo-damage spectra
ES_{i,j} i=1, . . . , m, j=1, . . . , n—extrapolated pseudo-damage spectra
SS_{i,j} j=1, . . . , n—extrapolated and superposed pseudo-damage spectra
PP_{i,j} i=1, . . . , m, j=1, . . . , n—test profiles (individual routes)
SPP_{i,j} j=1, . . . , n—test profiles (route mix)
P1 pseudo-damage spectrum calculation process
P2 extrapolation and superposition process
P3 test profile generation process
P4 reference signal processing process
P5 extrapolation subprocess
P6 superposition subprocess
S1 signal filter step
S2 classification step
S3 conversion step
S4 partial damage contribution calculation step
S5 cumulative damage calculation step
S6 pseudo-damage spectrum formation step

1-14: (canceled)

15. A method for generating a test profile (4), comprising:
a pseudo-damage spectrum calculation process (P1) calculating a plurality of pseudo-damage spectra (2.1, 2.2, . . . , 2.n) from a plurality of measurement signals (1.1, 1.2, . . . , 1.n) using a spectrum calculation algorithm, the plurality of pseudo-damage spectra (2.1, 2.2, . . . , 2.n) including a respective pseudo-damage spectrum (2.1, 2.2, . . . , 2.n) for each of the plurality of measurement signals (1.1, 1.2, . . . , 1.n), each of the plurality of measurement signals (1.1, 1.2, . . . , 1.n) being previously recorded during a route journey of a test vehicle;
an extrapolation and superposition process (P2) comprising an extrapolation subprocess (P5) and a superposition subprocess (P6), a plurality of extrapolated pseudo-damage spectra (7.1, 7.2, . . . , 7.n) being generated during the extrapolation subprocess (P5) by multiplying each of the pseudo-damage spectrum (2.1, 2.2, . . . , 2.n) by a proportionality constant, a superposed pseudo-damage spectrum (3) being generated during the superposition subprocess (P6) by adding together the plurality of extrapolated pseudo-damage spectra (7.1, 7.2, . . . , 7.n);
a reference signal processing process (P4), a reference signal pseudo-damage spectrum (17) being calculated during the reference signal processing process (P4) using the spectrum calculation algorithm on a reference signal (5) and, subsequently, an extrapolated reference signal pseudo-damage spectrum (6) is generated during the reference signal processing process (P4) by multiplying the reference signal pseudo-damage spectrum (17) by the proportionality constant; and
a test profile generation process (P3) generating a test profile (4) based on the superposed pseudo-damage spectrum (3) and the extrapolated reference signal pseudo-damage spectrum (6).

16. The method of claim 15, wherein the test profile (4) computationally satisfies the principle of damage equivalence with respect to the plurality of pseudo-damage spectra (2.1, 2.2, . . . , 2.n).

17. The method of claim 15, wherein the reference signal processing process (P4) is performed in parallel with one or both of the pseudo-damage spectrum calculation process (P1) or the extrapolation and superposition process (P2).

18. The method of claim 15, wherein the route journey includes a plurality of various routes of a route mix,
wherein each of the plurality of measurement signals (1.1, 1.2, . . . , 1.n) describes a time curve of a certain measurement variable for a respective route of the plurality of various route.

19. The method of claim 18, wherein the test profile generation process (P3) further generates multiple individual test profiles (8.1, 8.2, . . . , 8.n), each of the multiple individual test profiles (8.1, 8.2, . . . , 8.n) corresponding to the respective route.

20. The method of claim 19, wherein the test profile (4) corresponds to an entirety of the route mix (4),
wherein the test profile (4) and the multiple individual test profiles (8.1, 8.2, . . . , 8.n) include one or more of excitation and response profiles, profiles for single-point control and multi-point control, or profiles for damage.

21. The method of claim 15, wherein the pseudo-damage spectrum calculation process (P1) further comprises:
a signal filter step (S1) for filtering each of the plurality of measurement signals (1.1, 1.2, . . . , 1.n) using a plurality of band passes to create a plurality of filtered measurement signals;
a classification step (S2) forming a load spectrum from each of the plurality of filtered measurement signals by a classification, the classification including subdividing an entire amplitude range of each of the plurality of filtered measurement signals into classes and using a counting method to determine a number of stress cycles for an amplitude of each of the classes;
a conversion step (S3) comprising converting the amplitude of each of the stress cycles into a damage-equivalent amplitude without an average value using a Haigh diagram, and then sorting the damage-equivalent amplitudes in ascending order;
a partial damage contribution calculation step (S4) calculating a partial damage contribution by utilizing an S-N curve for the number of stress cycles at each of the damage-equivalent amplitudes;
a cumulative damage calculation step (S5) summing the partial damage contributions to obtain a cumulative damage for each of the plurality of filtered measurement signals, wherein each of the cumulative damages is a pseudo-damage figure; and
a pseudo-damage spectrum formation step (S6) forming the pseudo-damage spectra (2.1, 2.2, . . . , 2.n) from the pseudo-damage figures by representing the pseudo-damage figures as a function of band pass central frequencies of the plurality of band passes.

22. The method of claim 15, wherein the test profile generation process (P3) comprises one or both of a calculation of a noise profile or a calculation of a sweep profile.

23. The method of claim 22, wherein, when the test profile generation process (P3) comprises calculation of the sweep profile, conversion of damage to a damage-equivalent test amplitude is performed using (3.17):
$${S}_{U} ( f ) = {{S}_{Ref} ( f ) [ \frac{{D}_{U} ( f )}{{D}_{Ref} ( f )} ]}^{( \frac{1}{{k}_{WL}} )}$$
S_{U}(f) being a sought amplitude of the sweep profile, S_{Ref}(f) being an amplitude of the reference signal, D_{U}(f) being an ordinate of the pseudo-damage spectrum arising for monoharmonic vibration having the sought amplitude S_{U}, D_{Ref}(f) being an ordinate of the pseudo-damage spectrum of the reference signal with the S_{Ref}(f), and k_{WL} being a slope coefficient of an S-N curve, and
wherein, when the test profile generation process (P3) comprises calculation of the noise profile, conversion of the damage to a damage-equivalent power spectral density level is performed using (3.16):
$${PSD}_{U} ( f ) = {PSD}_{Ref} ( f ) \times {[ \frac{{D}_{U} ( f )}{{D}_{Ref} ( f )} ]}^{( \frac{2}{{k}_{WL}} )}$$
PSD_{U}(f) being a sought level of the power spectral density of the noise profile, PSD_{Ref}(f) being a level of the power spectral density of the reference signal, D_{U}(f) being the ordinate of the pseudo-damage spectrum arising for stochastic vibration with the sought level PSD_{U}, and D_{Ref}(f) being the ordinate of the PSS of the reference signal with the PSD_{Ref}(f), and k_{WL} being the slope coefficient of the S-N curve.

24. The method of 23, wherein an overall structure and an overall calculation sequence of the method are unchanged between the calculation of the sweep profile or the calculation of the noise profile with exception of the reference signal of a particular type and the test profile generation process (P3).

25. The method of claim 15, wherein the method is a computer-implemented method.

26. A system, comprising a computer for one or more of at least partially carrying out, at least partially coordinating, or at least partially controlling the method of claim 15.

27. A computer program comprising program code stored on a non-transitory computer-readable medium with software instructions to carry out the method of claim 15 when executed on a computer.

28. A computer-readable medium comprising computer program code for carrying out the method of claim 15.
